(19) United States
(12) Patent Application Publication
(10) Pub. No.: US 2012/0014768 A1
(43) Pub. Date: Jan. 19, 2012

(54) VACUUM PROCESSING APPARATUS

(75) Inventors: Tetsuya MIYASHITA, Nirasaki City (JP); Masamichi Hara, Nirasaki City (JP); Yasushi Mizusawa, Nirasaki City (JP); Toshiharu Hirata, Nirasaki City (JP)

(73) Assignee: TOKYO ELECTRON LIMITED, Tokyo (JP)

(21) Appl. No.: 13/181,011

(22) Filed: Jul. 12, 2011

(30) Foreign Application Priority Data
Jul. 13, 2010 (JP) 2010-159018
Mar. 31, 2011 (JP) 2011-080149

(51) Int. Cl. H01L 21/677

(52) U.S. Cl. 414/217

(57) ABSTRACT

In a vacuum processing apparatus, a process station includes processing regions arranged in a row at intervals to perform vacuum processing on substrates, the substrates being sequentially transferred between the processing regions from upstream to downstream; a first transport unit for transferring the substrates in a first preliminary vacuum chamber to the processing region at an upstream end; a second transport unit arranged between the adjacent processing regions; and a third transport unit for transferring the substrates from the processing region at a downstream end to a second preliminary vacuum chamber. The control unit outputs a control signal such that in the transfer operations in which the substrates are respectively transferred to the subsequent downstream processing regions from the first preliminary vacuum chamber to the processing region at the downstream end, time periods of at least two transfer operations partially or totally overlap with each other.

### CROSS-REFERENCE TO RELATED APPLICATIONS

This application claims priority to Japanese Patent Application Nos. 2010-159018 filed on Jul. 13, 2010 and 2011-080149 filed on Mar. 31, 2011, the entire contents of which are incorporated herein by reference.

### FIELD OF THE INVENTION

The present invention relates to a vacuum processing apparatus for performing vacuum processing on a substrate.

### BACKGROUND OF THE INVENTION

As a vacuum processing apparatus for performing vacuum processing on a substrate such as a semiconductor wafer (hereinafter, referred to as a “wafer”), there is known an apparatus called a cluster tool or multi-chamber system in which a plurality of processing chambers are radially connected to sides of a vacuum transfer chamber having a vacuum atmosphere therein, and wafers are loaded into and unloaded from the processing chambers by a common wafer transfer device (transport unit) disposed in the vacuum transfer chamber to be vertically movable and rotatable around a vertical axis. The wafer transfer device includes, e.g., two picks for supporting the wafers from the bottom side to perform loading and unloading of the wafers. A plurality of wafers sequentially are loaded into and unloaded from the processing chambers by an advance/retreat and rotation operation of the picks.

As vacuum processes performed in processing regions of the processing chambers, there are, e.g., a film forming process such as chemical vapor deposition (CVD) and physical vapor deposition (PVD), and a plasma process such as etching and ashing. Further, in this apparatus, a same process may be performed in parallel on wafers in some or all of the processing chambers (parallel process) or a plurality of different processes may be continuously performed on a wafer by sequentially transferring the wafer to the processing chambers (serial process).

In this apparatus, when vacuum processes have been completed almost simultaneously in, e.g., two processing chambers among a plurality of processing chambers, loading and unloading timing of the wafers in these processing chambers overlap with each other. In this case, until the wafer transfer device completes the transfer operation for one of the processing chambers, the wafer transfer device cannot perform loading of a next wafer into another processing chamber. Accordingly, another processing chamber is on standby. In the above-mentioned serial process, after processes are completed in the respective processing chambers, wafers are transferred, e.g., simultaneously from these processing chambers to different processing chambers to continuously perform processes. Accordingly, as the number of the processing chambers (the number of types of continuous processes) is greater, the number of standby wafers becomes large.

Further, as the processing time required for processing in each of the processing chambers becomes shorter, the loading and unloading timings of the wafers can more easily overlap with each other and the standby time of each in the processing chambers can become longer. Accordingly, even when, e.g., the processing time in each of the processing chambers is shortened in order to enhance a total throughput of the apparatus, the processing chamber may become on standby longer by the shortened time. Further, as the processing time becomes short, the transfer rate control increases, thereby making it difficult to improve a throughput.

Japanese Patent Application Publication Nos. H8-111449 and 2001-53131 disclose an apparatus for performing processing in a vacuum atmosphere, but do not take the above-mentioned problem into consideration. Japanese Patent Application Publication No. 2009-16727 discloses technology for performing loading and unloading of wafers W using two transfer arms in the processing chamber in an atmospheric atmosphere, but does not take processing in a vacuum atmosphere into consideration. Further, Japanese Patent Application Publication No. 2003-174070 (Paragraph [0031] and FIG. 1) discloses that processing units are provided around a transfer unit and substrates are raised almost simultaneously by arms of the transfer unit in the processing units such that a throughput is not controlled by the transfer time of the substrates. However, in Japanese Patent Application Publication No. 2003-174070, the transfer unit requires a mechanism for rotating the arms. Thus, the transfer unit becomes large-sized.

U.S. Pat. Nos. 6,059,507, 6,079,928 and 5,909,994 disclose load-lock structures for performing transfers of substrates between the atmospheric side and the vacuum side. However, in each of these structures, the transfer rate of a transfer arm at the atmospheric side cannot match with processing or transfer of substrates at the vacuum side.

### SUMMARY OF THE INVENTION

In view of the above, the present invention provides a vacuum processing apparatus in which when vacuum processing is performed on substrates in a plurality of processing regions, it is possible to reduce an entire foot print of the apparatus and shorten the time between completion of vacuum processing on the substrates and starting of vacuum processing on next wafers in each of the processing regions.

In accordance with an embodiment of the present invention, there is provided a vacuum processing apparatus for performing vacuum processing on substrates, including: a first preliminary vacuum chamber to which the substrates are loaded from a normal pressure atmosphere; a process station connected to the first preliminary vacuum chamber and maintained in a vacuum atmosphere; a second preliminary vacuum chamber connected to the process station, the substrates processed in the process station being unloaded from the process station to a normal pressure atmosphere; and a control unit for controlling an operation of the vacuum processing apparatus.

Further, the process station includes: a series of processing regions arranged in a row at intervals to perform vacuum processing on the substrates, the substrates being sequentially transferred from the processing region located at an upstream side to the processing region located at a downstream side; a first transport unit for transferring the substrates in the first preliminary vacuum chamber to the processing region located at an upstream end of the series of the processing regions; a second transport unit arranged between the processing regions adjacent to each other; and a third transport unit for transferring the substrates from the processing region located at a downstream end of the series of the processing regions to the second preliminary vacuum chamber. The control unit outputs a control signal such that in the transfer operations in which the substrates are respectively transferred to the subsequent downstream processing regions therefor from the first preliminary vacuum chamber to the processing region located at the downstream end of the series of the processing regions, time periods of at least two transfer operations partially or totally overlap with each other.

### BRIEF DESCRIPTION OF THE DRAWINGS

The objects and features of the present invention will become apparent from the following description of embodiments, given in conjunction with the accompanying drawings, in which:

FIG. 1 is a perspective view of a vacuum processing apparatus in accordance with an embodiment of the present invention;

FIG. 2 is a plan view of the vacuum processing apparatus;

FIG. 3 is a perspective view of a processing unit of the vacuum processing apparatus;

FIG. 4 is a perspective view of a transfer module of the vacuum processing apparatus;

FIG. 5 shows a longitudinal cross sectional view of the processing unit of the vacuum processing apparatus;

FIG. 6 is a transversal cross sectional view of the processing unit of the vacuum processing apparatus;

FIGS. 7 to 9 are longitudinal cross sectional views each showing a state in which a transfer of a wafer is performed in the processing unit of the vacuum processing apparatus;

FIGS. 10 to 17 are plan views showing operations of the vacuum processing apparatus;

FIG. 18 is a plan view of a vacuum processing apparatus in accordance with another embodiment of the present invention;

FIG. 19 is a plan view of a vacuum processing apparatus in accordance with still another embodiment of the present invention;

FIGS. 20 and 21 are plan views of a vacuum processing apparatus in accordance with still another embodiment of the present invention;

FIG. 22 is a plan view of a vacuum processing apparatus in accordance with still another embodiment of the present invention;

FIG. 23 is a plan view of a vacuum processing apparatus in accordance with still another embodiment of the present invention;

FIG. 24 is a plan view of a vacuum processing apparatus in accordance with still another embodiment of the present invention;

FIG. 25 is a plan view of a vacuum processing apparatus in accordance with still another embodiment of the present invention;

FIGS. 26 and 27 are respectively a plan view and a perspective view of a vacuum processing apparatus in accordance with still another embodiment of the present invention;

FIG. 28 is a plan view of a vacuum processing apparatus in accordance with still another embodiment of the present invention;

FIG. 29 is a plan view of a vacuum processing apparatus in accordance with still another embodiment of the present invention;

FIGS. 30 and 31 are respectively a perspective view and a longitudinal cross sectional view of the vacuum processing apparatus shown in FIG. 29;

FIG. 32 is an enlarged view of a region in the vicinity of the load-lock chamber in the vacuum processing apparatus in accordance with the embodiments of the present invention.

FIG. 33 is a longitudinal cross sectional view of the vacuum processing apparatus including the load-lock chamber shown in FIG. 32;

FIG. 34 is a longitudinal cross sectional view of the wafer transfer devices in the vacuum processing apparatus shown in FIG. 33;

FIGS. 35 and 36 are plan views each schematically showing the load-lock chamber shown in FIG. 32; and

FIGS. 37 to 45 are plan views showing operations of the vacuum processing apparatus including the load-lock chamber shown in FIG. 32.

### DETAILED DESCRIPTION OF THE EMBODIMENTS

Hereinafter, embodiments of the present invention will be described with reference to accompanying drawings, which form a part hereof.

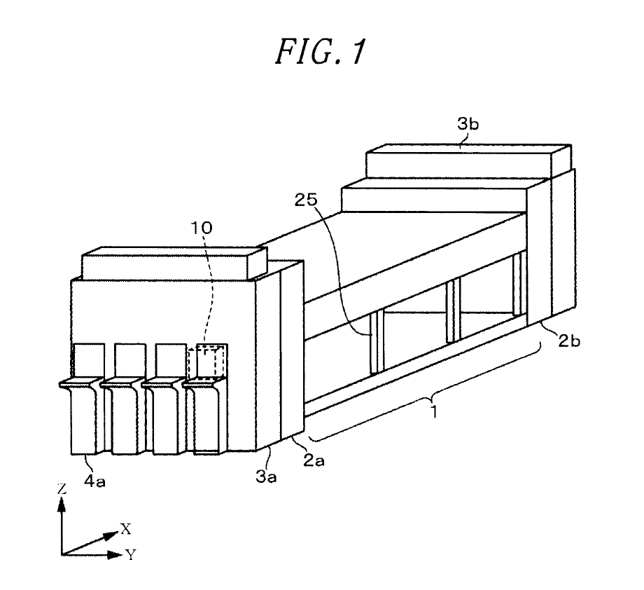

A vacuum processing apparatus in accordance with an embodiment of the present invention will be described with reference to FIGS. 1 to 9. First of all, an entire configuration of the vacuum processing apparatus will be described. The vacuum processing apparatus includes a process station 1 disposed to extend in an X direction (forward/backward direction) in order to perform a process on a semiconductor wafer (hereinafter, referred to as a “wafer”) W serving as a substrate in a vacuum atmosphere. The vacuum processing apparatus further includes a first load-lock chamber 2a for use in loading and a second load-lock chamber 2b for use in unloading, which are airtightly connected to longitudinal end sides of the process station 1 to perform loading and unloading of the wafer W to and from the process station 1. The first load-lock chamber 2a and the second load-lock chamber 2b are preliminary vacuum chambers, each having an inner atmosphere that can be switched between an atmospheric atmosphere and a vacuum atmosphere.

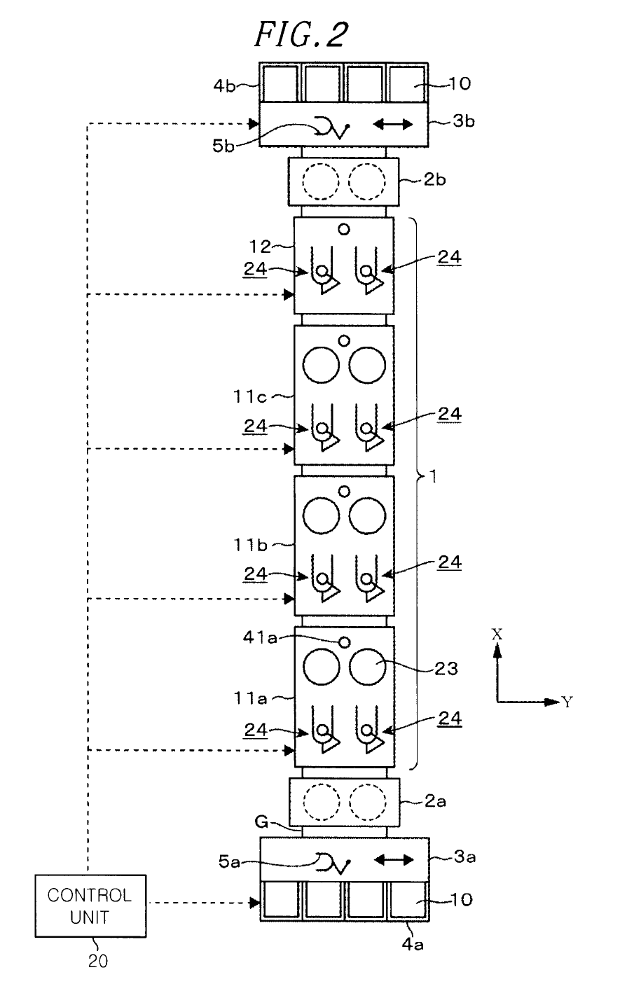

Each of the first and the second load-lock chambers 2a and 2b is configured to arrange two wafers W horizontally in a Y direction (perpendicular to the longitudinal direction of the process station 1) in FIG. 2. In each of the first and second load-lock chambers 2a and 2b, there are provided elevation pins (not shown) to raise wafers W received in each of the first and second load-lock chambers 2a and 2b from the bottom side and perform transfer of the wafers W to and from a wafer transfer device 24 that will be described later. Notation G in FIG. 2 represents a gate valve. Herein, as will be described later, wafers W are transferred from the first load-lock chamber 2a toward the second load-lock chamber 2b in the process station 1. Accordingly, in the following descriptions of the embodiment, the first load-lock chamber 2a and the second load-lock chamber 2b are respectively on the upstream and the downstream side with respect to the process station 1.

Atmospheric transfer chambers 3a and 3b having atmospheric (normal pressure) atmospheres therein are connected to the upstream side of the first load-lock chamber 2a and the downstream side of the second load-lock chamber 2b, respectively. In the atmospheric transfer chamber 3a (or 3b), mounting tables 4a (or 4b) forming loading ports are arranged, e.g., at four places in the Y direction. Each of FOUPs 10, serving as a transfer container and accommodating, e.g., twenty five (25) wafers W, is mounted on one of the mounting tables 4a and 4b. Transfer arms 5a and 5b, which are vertically movable, rotatable around a vertical axis and horizontally movable along the arrangement of the mounting tables 4a and 4b, are respectively provided as transfer units in the atmospheric transfer chambers 3a and 3b in order to perform transfer of wafers W between the first and the second load-lock chambers 2a and 2b and the FOUPs 10. Although the transfer arms 5a and 5b are schematically illustrated in FIG. 2, the transfer arms 5a and 5b are configured as multi-joint arms in the same way as the wafer transfer device 24 that will be described later.

The process station 1 will now be described in detail. The process station 1 includes a plurality of, e.g., three, processing units 11, each performing a vacuum process on the wafers W, and a transfer module 12 for unloading the wafers W, which have been processed while passing through the processing units 11, to the second load-lock chamber 2b. Reference numerals 11a, 11b and 11c are assigned to the three processing units 11, respectively. The processing units 11a, 11b and 11c and the transfer module 12 are sequentially and airtightly connected to each other in a row from the upstream side to the downstream side between the first load-lock chamber 2a and the second load-lock chamber 2b. In this embodiment, the processing units 11 are airtightly defined by defining walls forming sidewalls of the processing units 11 and arranged linearly. Further, loading and unloading of the wafers W are performed through the defining walls by opening gate valves G serving as partition valves provided at the defining walls.

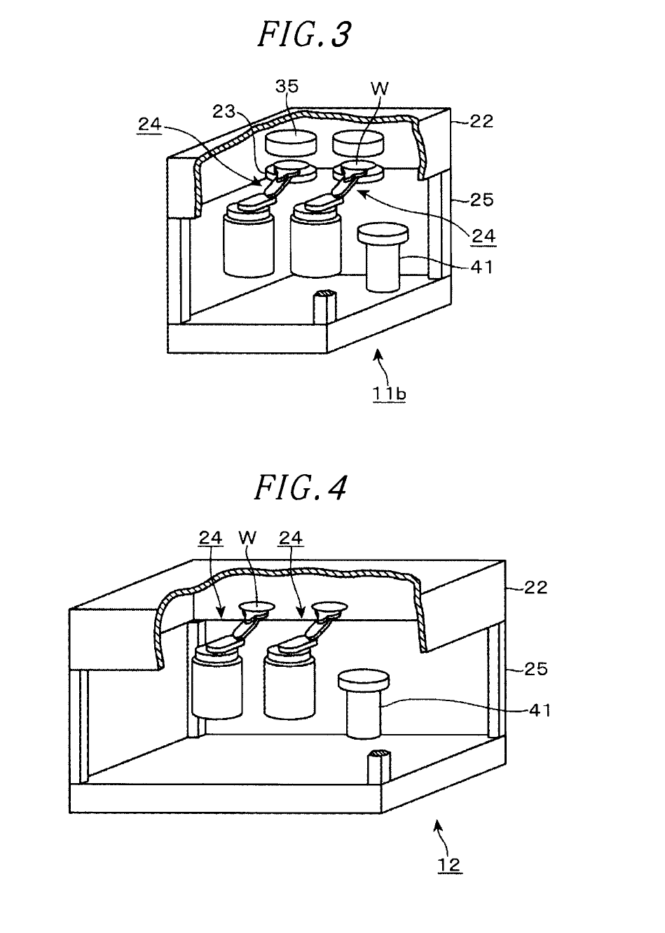

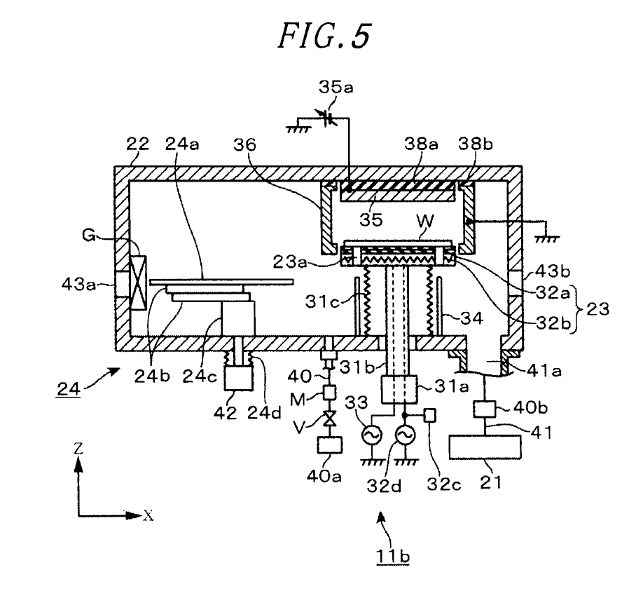

Since the processing units 11 have approximately the same configuration as will be described below, the description will be given with reference to FIG. 3 while the processing unit 11b being a second (central) unit from the upstream side in FIG. 2 serves as an example. The processing unit 11b includes a vacuum vessel 22 in which a vacuum atmosphere is maintained by a vacuum exhaust device 21 (see, FIG. 5) via a gas exhaust path 41, mounting portions (substrate mounting positions) 23 provided in the vacuum vessel 22 to mount the wafers W thereon such that a vacuum process is performed on the wafers W, and wafer transfer devices 24 that are transport units for use in loading (mounting) the wafers W on the mounting portions 23 from the processing unit 11a disposed on the upstream side of the processing unit 11b. In this example, the mounting portions 23 are arranged at two places in a direction perpendicular to the arrangement of the processing units 11a, 11b and 11c (in a transverse direction) to be separated from each other. The wafer transfer devices 24 are provided on the upstream side of the mounting portions 23, respectively. The wafer transfer devices 24 are arranged in parallel along the arrangement of the mounting portions 23. Reference numeral 25 denotes support members which support the vacuum vessel 22 from the bottom at a plurality of places. Further, FIG. 3 shows partially cutaway view of the vacuum vessel 22.

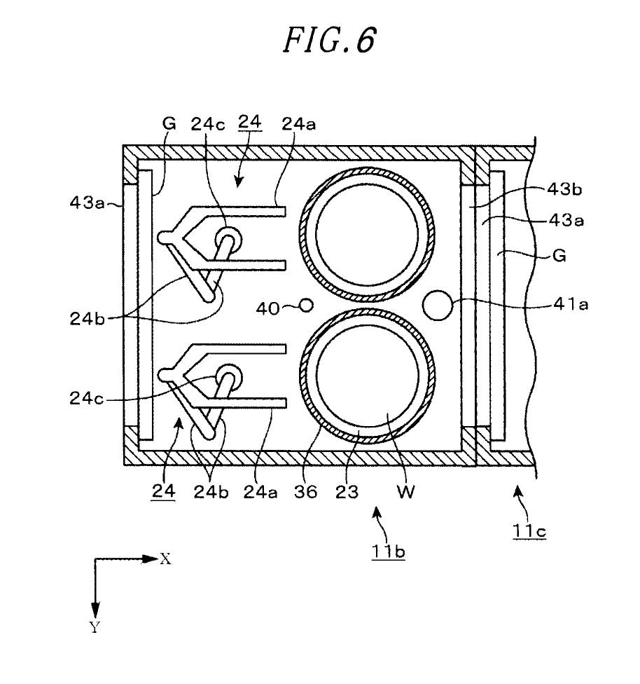

Subsequently, an inner region of the vacuum vessel 22 of the processing unit 11b will be described with reference to FIGS. 5 and 6. The processing unit 11b is an apparatus for performing a film forming process by physical vapor deposition (PVD). The mounting portions 23 are configured to be vertically movable by elevation units 31a provided below the vacuum vessel 22 between an upper position where a film forming process is performed and a lower position where transfer of the wafers W is performed. Each of the mounting portions 23 includes an electrostatic chuck 32a for electrostatically attracting and holding the wafer W on the corresponding mounting portion 23 and a heater 32b for heating the wafer W on the corresponding mounting portion 23.

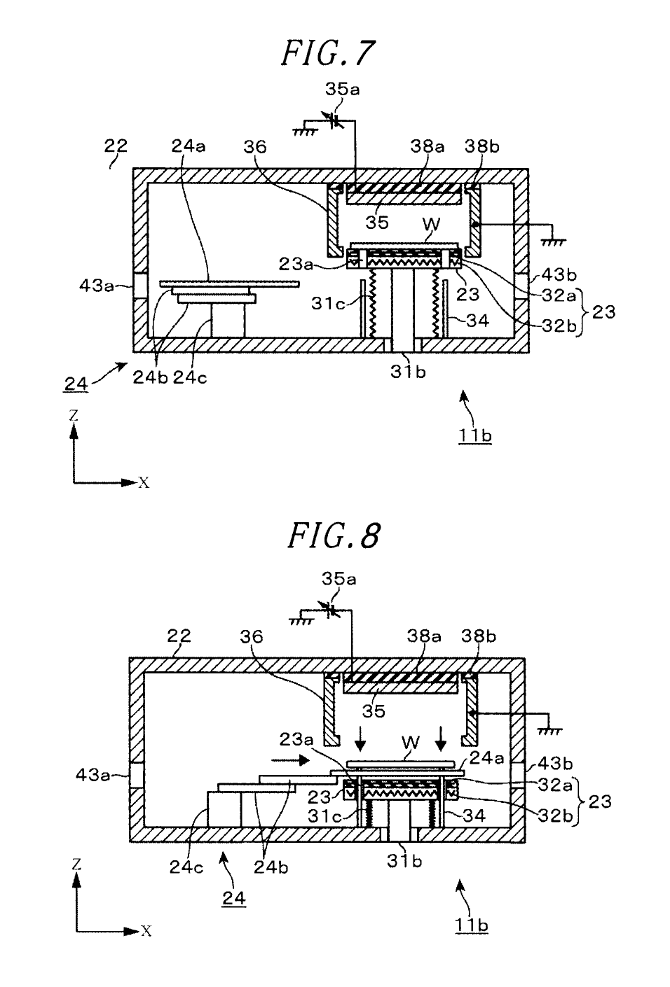

Further, support pins 34 are disposed on the bottom surface of the vacuum vessel 22, e.g., at three places to perform transfer of the wafer W from and to each of the wafer transfer devices 24. Each of mounting portions 23 includes through-holes 23a to pass the support pins 34 therethrough. Further, as shown in FIGS. 7 and 8, when the mounting portion 23 is moved down such that a mounting surface of the mounting portion 23 on which the wafer W is mounted is positioned below leading end portions of the support pins 34, the wafer W is supported by the support pins 34 from the bottom side to be separated from the mounting surface. In FIG. 5, reference numeral 31b denotes an elevation shaft for supporting the mounting portion 23 from the bottom side to be vertically movable by each of the elevation units 31a, and reference numeral 31c denotes a bellows airtightly enclosing the elevation shaft 31b in a circumferential direction between the lower surface of the mounting portion 23 and the bottom surface of the vacuum vessel 22. Further, in FIG. 5, reference numerals 32c and 32d denote power supplies connected to the electrostatic chuck 32a and the heater 32b, respectively, and reference numeral 33 denotes a high frequency power supply for bias, which attracts ions in the vacuum vessel 22 toward the wafer W mounted on the mounting portion 23, as will be described later.

A target 35 having, e.g., a circular plate shape and formed of, e.g., titanium (Ti) is provided at a ceiling surface of the vacuum vessel 22 to face the wafer W mounted on the mounting portion 23 positioned in the upper position thereof. A protection cover 36 having a substantially cylindrical shape is provided to externally surround the target 35 and the mounting portion 23 positioned in the upper position in a circumferential direction in order to suppress dispersion of titanium (Ti). In FIG. 5, reference numeral 35a denotes a direct current (DC) power supply for attracting ions of an argon gas generated in the vacuum vessel 22 toward the target 35, and also generating a plasma in a region between the mounting portion 23 and the target 35 by generating a potential difference in the corresponding region. An insulating member 38a is provided between the target 35 and the ceiling surface of the vacuum vessel 22. Further, in FIG. 5, reference numeral 38b denotes an insulating member provided between the protection cover 36 and the ceiling surface of the vacuum vessel 22. A region surrounded by the target 35, the mounting portion 23 and the protection cover 36 is a processing region in which a film forming process is performed on the wafer W.

One end of a gas supply line 40 for supplying an argon (Ar) gas or the like for plasma generation into the vacuum vessel 22 is opened at the bottom surface of the vacuum vessel 22 at a position which is closer to the wafer transfer device 24 than a periphery of the mounting portion 23. The other end of the gas supply line 40 is connected to a gas source 40a through a valve V and a mass flow controller M. Further, a gas exhaust opening 41a that is an opening end of the gas exhaust path 41 extending from the vacuum exhaust device 21 is formed on the bottom surface of the vacuum vessel 22. The gas exhaust path 41 is provided with a mass flow controller 40b including a butterfly valve or the like.

In the side surface of the vacuum vessel 22, a loading opening 43a for loading the wafer W into the vacuum vessel 22 and an unloading opening 43b for unloading the wafer W from the vacuum vessel 22 are respectively formed at the upstream side (on the processing unit 11a side) and the downstream side (on the processing unit 11c side). A width dimension (dimension in the Y direction) of the loading opening 43a and that of the unloading opening 43b are set such that a pick 24a supporting the wafer W can move back and forth therethrough. Further, a height dimension of the loading opening 43a and that of the unloading opening 43b are set so as to satisfy an elevation stroke when the wafer W is transferred between the wafer transfer device 24 and the mounting portion 23. Further, a gate valve G is provided to airtightly seal each of the loading opening 43a and the unloading opening 43b. In this example, the gate valve G is used in common between adjacent processing units 11. Specifically, the gate valve G between the adjacent processing units 11 is disposed in an inner region of the vacuum vessel 22 of the processing unit 11 located at the downstream side among the adjacent processing units 11. Further, the gate valve G is schematically illustrated in FIG. 2.

The wafer transfer device 24 is configured, as shown in FIGS. 5 and 6, as a multi-joint arm including a base 24c, e.g., two arms 24b stacked on the base 24c, and the pick 24a attached to a lending end portion of an upper one of the arms 24b. Further, the wafer transfer device 24 is supported to be rotatable around its vertical axis and vertically movable by a driving unit 42 provided below the vacuum vessel 22, and the pick 24a thereof is movable back and forth along the arrangement of the processing units 11a, 11b and 11c. An extension stroke of the wafer transfer device 24 is set to have a length capable of accessing not only the wafer W on the mounting portion 23 of the processing unit 11b but also the wafer W on the mounting portion 23 of the processing unit 11a located at the upstream side of the processing unit 11b. Reference numeral 24d in FIG. 5 denotes a bellows.

Now, the transfer of the wafer W between the wafer transfer device 24 and the mounting portion 23 will be described. First, when the mounting portion 23 supporting the wafer W thereon is moved down such that the wafer W is relatively raised from the mounting portion 23 by the support pins 34, the wafer transfer device 24 moves the pick 24a to be positioned between the upper surface of the mounting portion 23 and the lower surface of the wafer W. Then, the pick 24a picks up and receives the wafer W supported by the support pins 34 and then retreats toward the base 24c. Further, when the wafer W is being mounted on the mounting portion 23, the wafer transfer device 24 operates in a reverse sequence to the sequence followed when the wafer W is being received.

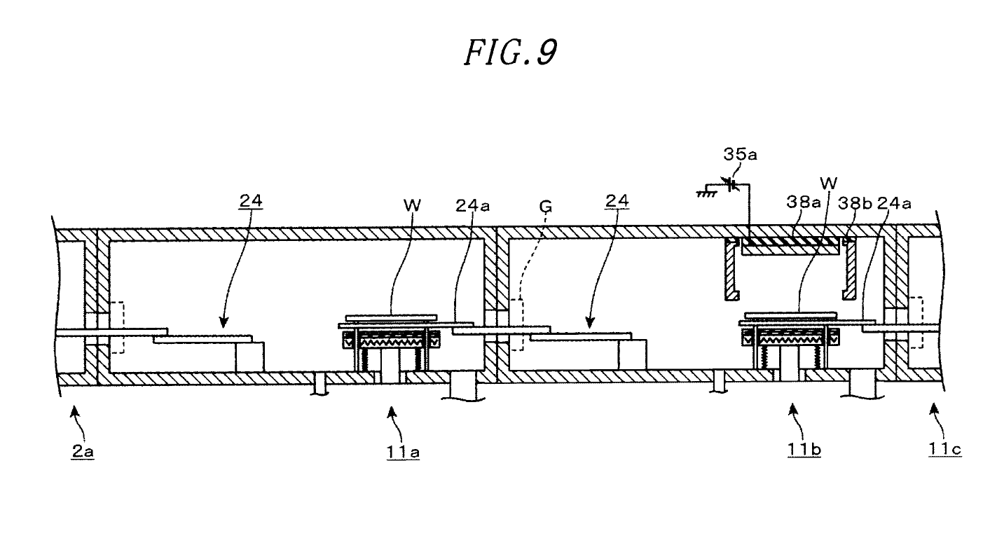

As mentioned above, the wafer transfer device 24 of the processing unit 11b is configured so as to receive the wafer W from the mounting portion 23 of the processing unit 11a located at the upstream side of the processing unit 11b. FIG. 9 shows an operation of receiving the wafer W, wherein the wafer transfer device 24 of the processing unit 11b is rotated around a vertical axis such that the leading end portion of the pick 24a is oriented toward the upstream side, and then advances the pick 24a into the processing unit 11a through the loading opening 43a of the processing unit 11b and the unloading opening 43b of the processing unit 11a. Accordingly, the pick 24a is positioned below the wafer W supported by the support pins 34 of the processing unit 11a. While the transfer of the wafer W is performed from the processing unit 11a to the processing unit 11b, the transfers of wafers W in other processing units 11 are also performed by instructions from a control unit 20. That is, loading and unloading of the wafers W are performed in the three processing units 11a, 11b and 11c at the same time by instructions from the control unit 20 as will be described later in detail. FIG. 9 also illustrates a state in which the wafer transfer device 24 of the processing unit 11c located at the downstream side of the processing unit 11b unloads the wafer W from the processing unit 11b, and a state in which the wafer transfer device 24 of the processing unit 11a unloads the wafer W from the first load-lock chamber 2a.

The processing unit 11c located at the downstream end among the three processing units 11a, 11b and 11c is a unit for performing a film forming process by physical vapor deposition (PVD) in the same way as the processing unit 11b, and has approximately the same configuration as the processing unit 11b, but includes the target 35 formed of copper (Cu). The processing unit 11a located at the upstream end is a unit for performing a heating process in a vacuum atmosphere in order to remove (reduce), e.g., organic components or moisture adsorbed on the surface of the wafer W. As illustrated in FIG. 9, the processing unit 11a has a state in which the target 35 and the protection cover 36 are removed from the processing unit 11b. The wafer transfer device 24 of the processing unit 11a serves as a transport unit for use in loading the wafer W from the first load-lock chamber 2a to the processing unit 11a.

Further, the transfer module 12 connected to the processing unit 11c at the downstream side of the processing unit 11c includes, as schematically shown in FIG. 4, the vacuum vessel 22, two wafer transfer devices 24 each having the pick 24a, and the vacuum exhaust device 21 for vacuum evacuating the vacuum vessel 22. The wafer transfer devices are arranged in parallel to the arrangement of the mounting portions 23 of the processing unit 11c. The wafer transfer devices 24 of the processing unit 11c serve as transport units for use in unloading the wafers W from the processing unit 11c located at the downstream end to the second load-lock chamber 2b.

The vacuum processing apparatus includes, as shown in FIG. 2, the control unit 20 having, e.g., a computer. The control unit 20 includes a data processing unit having a CPU, a memory and programs and the like. The programs are used to control a series of operations of the vacuum processing apparatus. The programs include a transfer program for determining a transfer sequence of the wafers W and a process program relating to processing of the wafers W in the processing units 11. The transfer program is configured to, e.g., simultaneously perform an operation of transferring the wafers W from the first load-lock chamber 2a to the processing unit 11a located at the upstream end, an operation of transferring the wafers W from the processing unit 11c located at the downstream end to the second load-lock chamber 2b, and an operation of transferring the wafers W from the processing units 11a and 11b to the processing units 11b and 11c on the downstream sides, respectively.

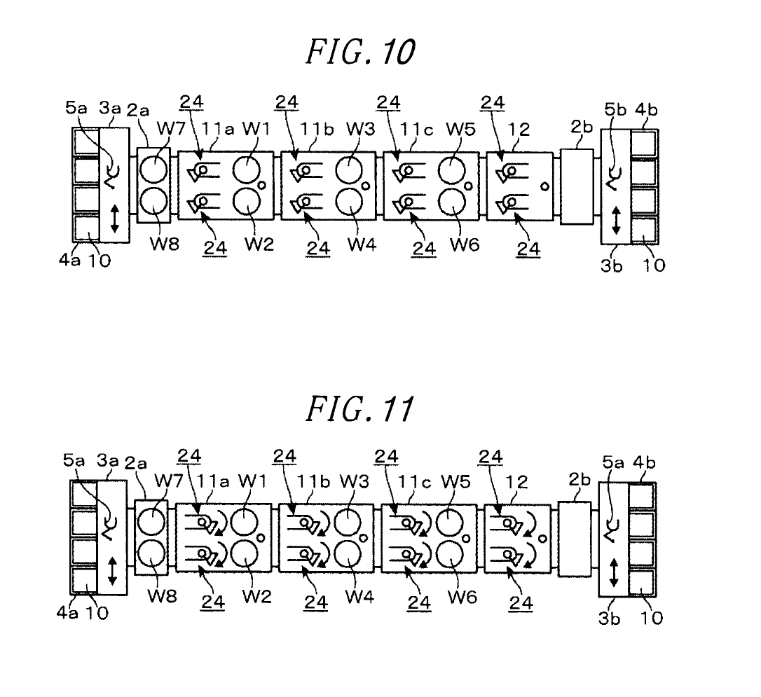

Next, the operations of the vacuum processing apparatus will be described with reference to FIGS. 10 to 17. A series of operations described herein are conducted by the above-described programs. FIG. 10 illustrates a state in which processing is continuously performed on a plurality of wafers W in the vacuum processing apparatus. That is, two wafers W are received into each of the processing units 11a, 11b and 11c. Each of the processing units 11a, 11b and 11c has, e.g., a state in which processing is about to be performed (a state in which the mounting portions 23 that have received the wafers W from the wafer transfer devices 24 are moved up). Further, two wafers W are loaded into the first load-lock chamber 2a located at the upstream side and at the same time the first load-lock chamber 2a has a vacuum atmosphere therein.

In this case, in order to easily understand the flow of the wafers W in the process station 1, reference numerals are assigned to the respective wafers W. That is, wafers W1 and W2 are received into the processing unit 11a, wafers W3 and W4 are received into the processing unit 11b, wafers W5 and W6 are received into the processing unit 11c, and wafers W7 and W8 are received into the first load-lock chamber 2a. Further, gate valves G are airtightly closed between the processing units 11a and 11b, between the processing units 11b and 11c, and between the processing units 11a and 11c and the first and the second load-lock chambers 2a and 2b, respectively. Hereinafter, vacuum processing performed in the processing units 11a, 11b and 11c will be described.

In the processing unit 11a, the vacuum vessel 22 is supplied with, e.g., an argon gas or the like while vacuum evacuated. Then, the wafers W1 and W2 are heated up to a temperature ranging from, e.g., about 265° C. to 400° C. (a temperature of about 300° C. in this embodiment). By such a heating process, organic substance or moisture adsorbed on the surfaces of the wafers W1 and W2 is gasified and evacuated.

In the processing unit 11b, the mounting portions 23 are set to be in upper positions such that the wafers W3 and W4 are close to the targets 35, respectively. Then, the vacuum vessel 22 is supplied with an argon gas or the like for plasma generation while vacuum evacuated. Further, a DC voltage is applied to each of the targets 35 from the DC power supply 35a while the wafers W3 and W4 are heated. Accordingly, the gas is converted into a plasma in a processing region between the wafers W3 and W4 and the targets 35 by a potential difference generated between the mounting portions 23 and the targets 35, respectively. Ions in the plasma are attracted to each of the targets 35 by the voltage applied from the DC power supply 35a to generate titanium particles by sputtering of the targets 35. The titanium particles are converted into ions by the plasma while falling down from the targets 35 and then attracted to the wafers W3 and W4 on the mounting portions 23 by the bias high frequency power supply 33 to collide with the wafers W3 and W4. When the targets 35 are kept sputtering and the titanium ions are attracted to the wafers W3 and W4, continuously, titanium films are formed on the surfaces of the wafers W3 and W4, respectively. In this case, since the protection covers 36 are disposed between the targets 35 and the mounting portions 23, metal particles of the targets 35 hardly disperse toward, e.g., the wafer transfer devices 24.

In the processing unit 11c, in the same way as the processing unit 11b, if the targets 35 made of copper are kept sputtering, copper films are formed on the surfaces of the wafers W5 and W6, respectively.

In this embodiment, although the vacuum processes in the processing units 11a, 11b and 11c have been described respectively for easy understanding, the vacuum processes are actually started at the same timing (simultaneously). Specifically, in the processing units 11a, 11b and 11c, mounting the wafers W on the mounting portions 23 and vacuum evacuating the vacuum vessels 22 are performed at the same timing. In this case, “simultaneously (at the same time)” not only represents the same timing, but also includes a case where processing is started at the same time in the processing units 11a, 11b and 11c even when there are time differences of about five seconds in the transfer operations of the respective wafer transfer devices 24.

Subsequently, when respective vacuum processes have been completed in the processing units 11a, 11b and 11c, the gas supply into the vacuum vessels 22 and the plasma generation are stopped. Then, as shown in FIG. 11, in the processing units 11a, 11b and 11c and the transfer module 12, the wafer transfer devices 24 are rotated simultaneously such that the picks 24a of the wafer transfer devices 24 are oriented toward the upstream sides, respectively. Further, the mounting portions 23 of the processing units 11a, 11b and 11c are moved down at the same time such that the wafers W are supported by the support pins 34 from the bottom sides (separated from the mounting portions 23). Further, in the first load-lock chamber 2a, the wafers W are lifted up from the bottom side by using elevating pins (not shown).

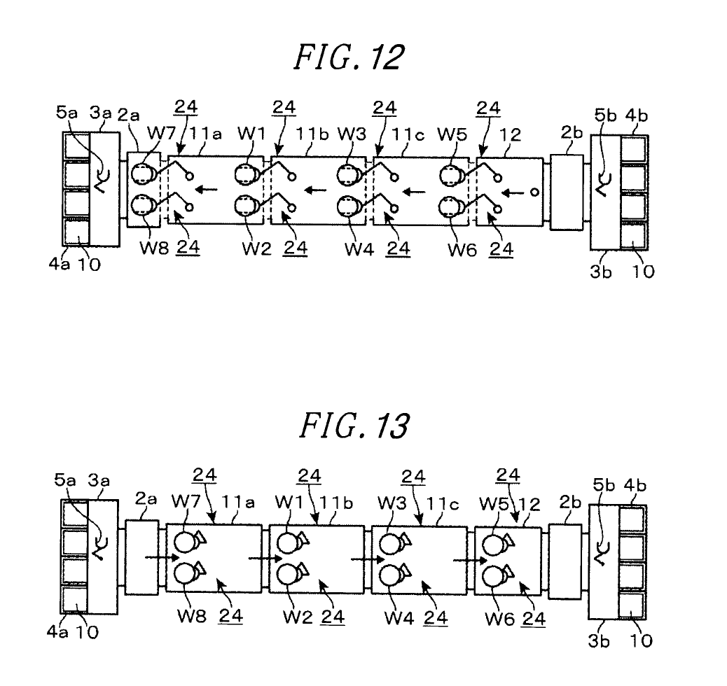

Next, the gate valves G between the processing units 11a, 11b and 11c and between the processing unit 11a and the first load-lock chamber 2a are opened simultaneously, and as shown in FIG. 12, the picks 24a of the respective wafer transfer devices 24 are extended to their upstream sides at the same time such that the picks 24a are positioned below the wafers W in their upstream sides, respectively. Further, the wafer transfer devices 24 are raised slightly such that the wafers W are received on the picks 24a. Thereafter, as shown in FIG. 13, the picks 24a are retreated toward the downstream sides at the same time such that the picks 24a return into the original positions in the processing units 11a, 11b and 11c and the transfer module 12 where the respective wafer transfer devices 24 are disposed. Consequently, the wafers W are loaded into the processing units 11a, 11b and 11c and the transfer module 12 at the same time such that the wafers W7 and W8 are received into the processing unit 11a, the wafers W1 and W2 are received into the processing unit 11b, the wafers W3 and W4 are received into the processing unit 11c, and the wafers W5 and W6 are received into the transfer module 12.

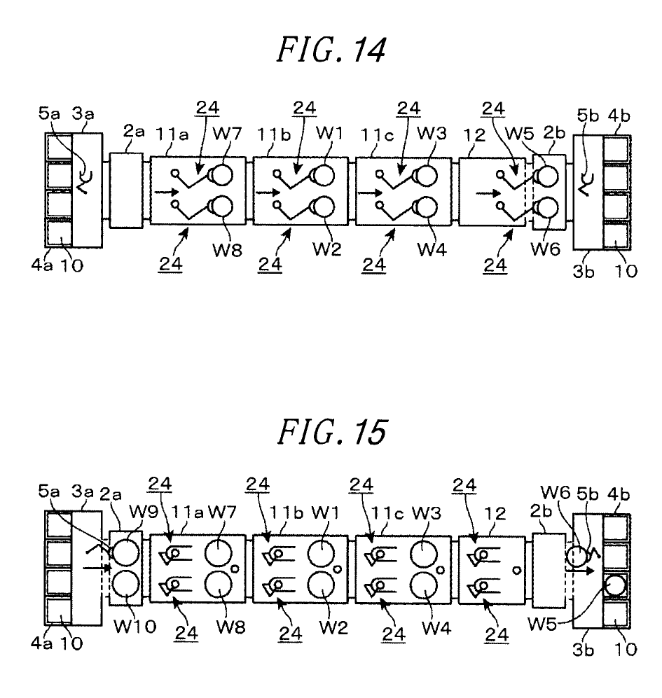

Then, the gate valves G between the processing units 11a, 11b and 11c and between the first load-lock chamber 2a and the processing unit 11a are airtightly closed, and at the same time the gate valve G between the transfer module 12 and the second load-lock chamber 2b is opened. Further, as shown in FIG. 14, the wafer transfer devices 24 are rotated simultaneously such that the leading end portions of the respective picks 24a are oriented toward the downstream sides, and the picks 24a of the respective wafer transfer devices 24 are extended toward the downstream sides. Accordingly, the wafers W are positioned above the mounting portions 23 of the processing units 11a, 11b and 11c, respectively, and the wafers W5 and W6 of the transfer module 12 are loaded into the second load-lock chamber 2b. Further, the wafers W are mounted on the mounting portions 23 and loaded into the second load-lock chamber 2b by cooperation of the wafer transfer devices 24 and the support pins 34 (elevating pins (not shown) in the second load-lock chamber 2b). Then, the wafer transfer devices 24 are retreated toward the bases 24c, respectively. Further, the gate valve G between the processing unit 11c and the second load-lock chamber 2b is airtightly closed.

By the above-described operations of the wafer transfer devices 24, the transfer of the wafers W7 and W8 from the first load-lock chamber 2a to the processing unit 11a, the transfer of the wafers W1 and W2 from the processing unit 11a to the processing unit 11b, the transfer of the wafers W3 and W4 from the processing unit 11b to the processing unit 11c, and the transfer of the wafers W5 and W6 from the processing unit 11c to the second load-lock chamber 2b are performed at the same time.

Further, in the processing units 11a, 11b and 11c, the above-described vacuum processes are performed on the wafers W1, W2, W3, W4, W7 and W8. That is, a removal process of moisture and the like is performed on the wafers W7 and W8, and a film forming process of a titanium film is performed on the wafers W1 and W2. Further, a film forming process of a copper film is performed on the wafers W3 and W4. Consequently, while processing is performed on those wafers W, loading of wafers W9 and W10 to the first load-lock chamber 2a and unloading of the wafers W5 and W6 from the second load-lock chamber 2b are performed as shown in FIG. 15. Specifically, an inner atmosphere of the first load-lock chamber 2a is changed from the vacuum atmosphere to the atmospheric atmosphere, and the gate valve G between the atmospheric transfer chamber 3a and the first load-lock chamber 2a is opened. Further, the wafers W9 and W10 are taken out from the FOUPs 10 by the transfer arm 5a of the atmospheric transfer chamber 3a and loaded into the first load-lock chamber 2a. Further, the gate valve G between the atmospheric transfer chamber 3a and the first load-lock chamber 2a is airtightly closed such that the inner atmosphere of the first load-lock chamber 2a is set to the vacuum atmosphere.

Similarly, in the second load-lock chamber 2b, an inner atmosphere of the second load-lock chamber 2b is set to the atmospheric atmosphere, and the gate valve G between the second load-lock chamber 2b and the atmospheric transfer chamber 3b is opened. Further, the wafers W5 and W6 are loaded into the FOUPs 10 of the atmospheric transfer chamber 3b from the second load-lock chamber 2b by the transfer arm 5b of the atmospheric transfer chamber 3b. Thereafter, the gate valve G is airtightly closed such that the inner atmosphere of the second load-lock chamber 2b is set to the vacuum atmosphere. Accordingly, if the wafer transfer devices 24 of the processing unit 11a and the transfer module 12 access subsequently to the first and the second load-lock chambers 2a and 2b respectively, the first load-lock chamber 2a is found to have received two wafers W and the second load-lock chamber 2b is found to be empty.

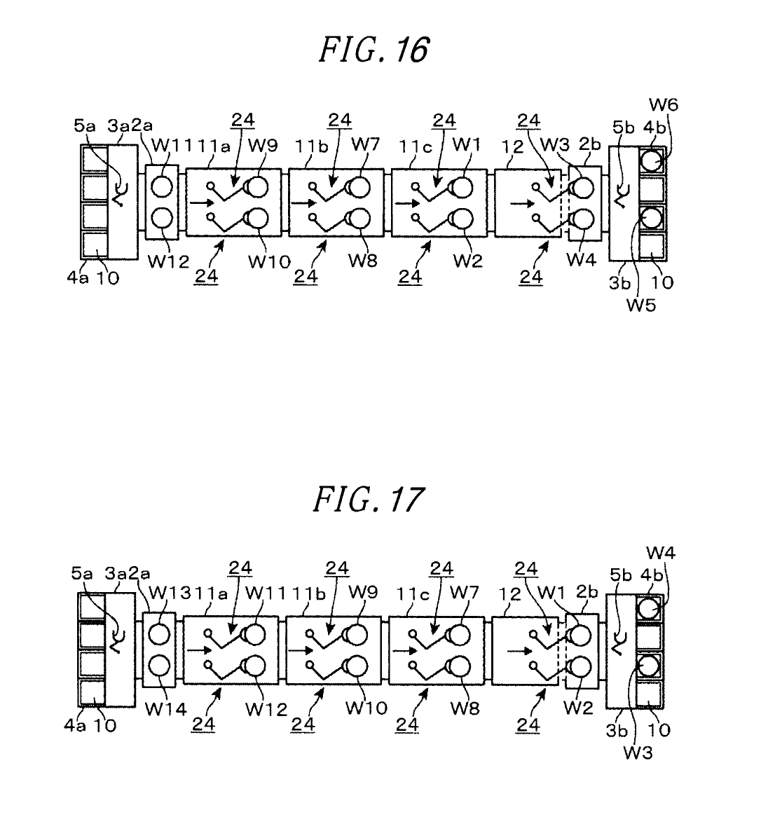

Next, when the vacuum processes are completed in the processing units 11a, 11b and 11c, as shown in FIG. 16, the wafers W of the upstream sides are transferred to the downstream sides simultaneously by the wafer transfer devices 24 as described above. Namely, the wafers W3 and W4 are loaded into the second load-lock chamber 2b, the wafers W1 and W2 are transferred into the processing unit 11c, and then copper films are formed on the surfaces of the titanium films. Further, the wafers W7 and W8 are transferred into the processing unit 11b and titanium films are formed thereon. The wafers W9 and W10 are transferred into the processing unit 11a and a removal process of moisture and the like is performed thereon. Further, the wafers W3 and W4 loaded into the second load-lock chamber 2b are returned to the FOUPs 10 and unprocessed wafers W11 and W12 are loaded into the first load-lock chamber 2a. When the above film forming processes and the removal process are completed, the wafers W are transferred simultaneously again, so that the wafers W1 and W2 on which the titanium and copper films have been stacked are loaded into the second load-lock chamber 2b, as shown in FIG. 17. Simultaneously, the wafers W7 to W12 are transferred from the upstream sides to the respective subsequent downstream sides, and unprocessed wafers W13 and W14 are loaded in the first load-lock chamber 2a in the same way. Then, a removal process of moisture and the like and a film forming process of a titanium film and a film forming process of a copper film are sequentially performed on each of the wafers W.

In accordance with the above-described embodiment, a plurality of processing regions (the mounting portions 23), in which vacuum processes are performed respectively, are arranged in a row at intervals, and the wafer transfer devices 24 are provided between the processing regions to simultaneously transfer the wafers W from the upstream side to the downstream side in the respective processing regions. Accordingly, it is possible to reduce an entire foot print of the apparatus and also shorten the time from completion of vacuum processing on the wafers to start of next vacuum processing on the subsequent wafers W in the respective processing regions. Consequently, since the time required for the transfer of the wafers W in the entire processing flow of the apparatus becomes very short, it is possible to extremely shorten the time for transfer rate control in which a throughput of the apparatus is controlled by transfer rates of the wafer transfer devices 24. As a result, since the time required for a series of processes of the wafers W becomes short by reducing the processing time in the processing units 11a, 11b and 11c, it is possible to improve a throughput of the apparatus by an amount corresponding to a reduction in the processing time in the processing units 11a, 11b and 11c.

In the above-described embodiment, it is controlled to simultaneously perform the operation of transferring the wafers W in the first load-lock chamber 2a to the processing unit 11a located at the upstream end by the wafer transfer devices 24 of the processing unit 11a, the operation of transferring the wafers W in the upstream processing units 11a and 11b to their downstream processing units 11b and 11c respectively by the wafer transfer devices 24 of the processing units 11b and 11c, and the operation of transferring the wafers W of the processing unit 11c located at the downstream end to the second load-lock chamber 2b by the wafer transfer devices 24 of the transfer module 12. That is, time periods for respective transfer operations of the wafers W between the first load-lock chamber 2a and the second load-lock chamber 2b may overlap with each other.

However, in the embodiment of the present invention, it is not limited to a case where the transfer operations are simultaneously performed as described above. Specifically, in order to obtain an effect of ensuring a high throughput through the entire transfer operations in which the wafers W are respectively transferred to the subsequent downstream substrate mounting positions (the mounting portion 23 and the second load-lock chamber 2b) from the first load-lock chamber 2a to the processing unit 11c located at the downstream end in the row of the processing regions, a control signal may be outputted such that the time periods of at least two transfer operations of the entire transfer operations partially or totally overlap with each other. That is, it is preferable as long as the time required for a series of transfer operations is shorter than a total time for which the wafers W in the first load-lock chamber 2a are sequentially transferred toward the downstream side to reach the second load-lock chamber 2b.

Specific examples for the above-described transfer operations of the wafers W in accordance with the embodiment of the present invention will be listed.

### First Example

In the three processing units 11a, 11b and 11c, for example, the wafers W are transferred from the processing unit 11b and the processing unit 11c located at the downstream end to the processing unit 11c and the second load-lock chamber 2b, respectively, and then the wafers W are transferred from the first load-lock chamber 2a and the processing unit 11a located at the upstream end to the processing unit 11a and the processing unit 11b, respectively. In this case, all time periods, for which the wafers W are transferred from the processing unit 11b and the processing unit 11c to the processing unit 11c and the second load-lock chamber 2b respectively, overlap with each other. Further, all time periods, for which the wafers W are transferred from the first load-lock chamber 2a and the processing unit 11a to the processing unit 11b and the processing unit 11c respectively, overlap with each other.

### Second Example

In the three processing units 11a, 11b and 11c, for example, the wafers W are transferred from the processing unit 11c to the second load-lock chamber 2b at the downstream side of the processing unit 11c; before the transfer of the wafers W to the second load-lock chamber 2b has been completed, the wafers W are transferred to the processing unit 11c from the processing unit 11b being one unit located at the upstream side of the processing unit 11c; before the transfer of the wafers W to the processing unit 11c has been completed, the wafers W are transferred to the processing unit 11b from the processing unit 11a; and before the transfer of the wafers W to the processing unit 11b has been completed, the wafers W are transferred to the processing unit 11a from the first load-lock chamber 2a. In this case, the time periods for which the wafers W are transferred between the adjacent substrate mounting positions (the first load-lock chamber 2a, the mounting portions 23 and the second load-lock chamber 2b) may partially overlap with each other.

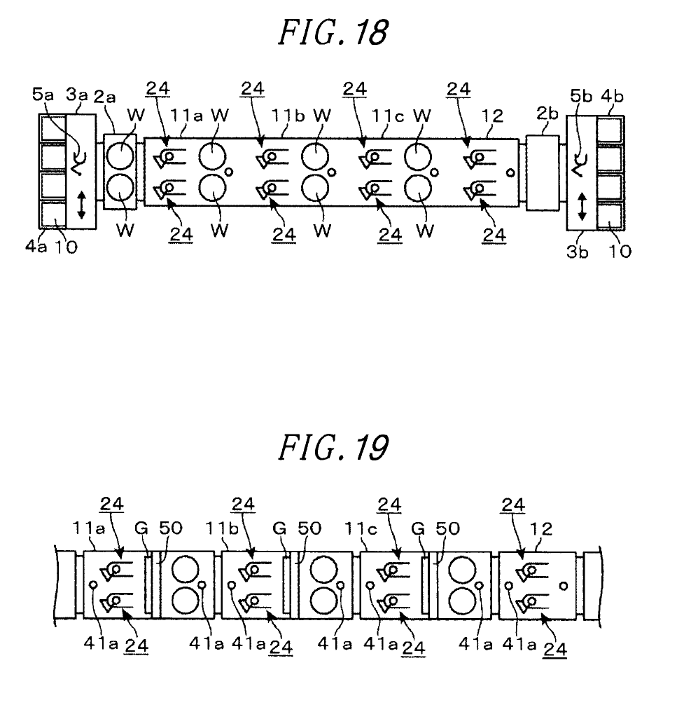

Although the gate valves G are respectively provided between the processing units 11a and 11b and between processing units 11b and 11c in the above-described embodiment, as shown in FIG. 18, the processing units 11a, 11b and 11c and the transfer module 12 may be arranged in one common vacuum vessel 22 without the gate valves G. In this case, the respective processes are preformed by adjusting a pressure of the common vacuum vessel 22 to fall in a range from, e.g., about 13.33 to 1.33×10⁻² Pa (1×10⁻¹ to 1×10⁻⁴ Torr).

The respective processes and the transfer sequence of the wafers W in this case are similar to those in the above-described embodiment, and thus a description thereof is omitted. Since the protection cover 36 is provided between the wafer W and the target 35, dispersion of metal particles and the like from one target 35 to the other target 35 is suppressed. Further, the processing units 11a, 11b and 11c can be directly connected to each other without the gate valves G. Accordingly, it is possible to reduce a foot print of the apparatus by an installation space of the gate valves G, and simplify the configuration of the apparatus. Further, since there is no operation of opening/closing the gate valves G, the wafers W can be immediately transferred without waiting the completion of the opening/closing operations of the gate valves G, thereby improving a throughput. In this case, one vacuum exhaust device 21 may be used in common for the processing units 11a, 11b and 11c and the transfer module 12.

Further, although the mounting portions 23 and the wafer transfer devices 24 are arranged in one common vacuum vessel 22, a partition wall 50 may be airtightly provided in at least one place between the mounting portions 23 and the wafer transfer devices 24, as shown in FIG. 19, and a gate valve (partition valve) G may be provided to airtightly open and close the partition wall 50. FIG. 19 illustrates an example in which the partition wall 50 and the gate valve G are provided in each of the processing units 11a, 11b and 11c. Further, gas exhaust openings 41a are formed in both regions (of the region where the mounting portions 23 is disposed and the region where the wafer transfer devices 24 is disposed) divided by the partition wall 50, respectively.

In this case, for example, it is possible to prevent particles and the like from traveling between the mounting portions 23 and the wafer transfer devices 24. Accordingly, for example, gas shower heads for supplying an organic gas including metal such as ruthenium (Ru) to the wafers W mounted on the mounting portions 23 may be provided instead of the targets 35 to form ruthenium films on the wafers W by chemical vapor deposition (CVD).

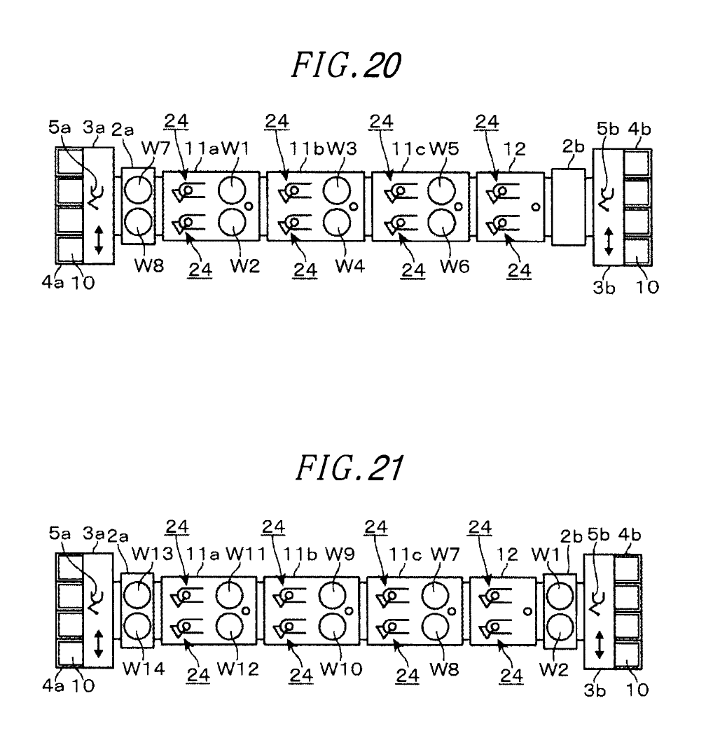

Further, although different processes (serial process) are respectively performed in the processing units 11, the same process, e.g., a film forming process of forming any one of a Ru film, a Ti film and a W film through CVD, may be performed in the processing units 11. In this case, when processing is started in the vacuum processing apparatus, unprocessed wafers W1 to W6 are loaded into the processing units 11, as shown in FIG. 20. Specifically, the wafers W5 and W6 are loaded into the processing unit 11c through the first load-lock chamber 2a and the processing units 11a and 11b while no process is performed thereon in the processing units 11a and 11b. Similarly, the wafers W3 and W4 are loaded into the processing unit 11b while no process is performed thereon in the processing unit 11a. The transfer operations of the wafers W1 to W6 are performed, e.g., at the same time as described above. Further, after processing is completed in the processing units 11a, 11b and 11c, the wafers W1 to W6 are transferred to the second load-lock chamber 2b while unprocessed wafers W7 to W12 are transferred to the processing units 11a, 11b and 11c in the same way, as shown in FIG. 21. Thereafter, the unprocessed wafers W7 to W12 are processed. As described above, when parallel processing is performed on the wafers W, the same effect can be obtained.

Further, although an example of performing different processes in the respective processing units 11 (i.e., a case where a removal process of moisture and the like, a film forming process of a titanium film and a film forming process of a copper film are sequentially performed in the three processing units 11a, 11b and 11c, respectively) has been described, for example, a removal process of moisture and the like, a cleaning process for performing pre-cleaning on the surfaces of the wafers W, a film forming process of a Ta film by PVD and a film forming process of a Cu film by PVD may be sequentially performed.

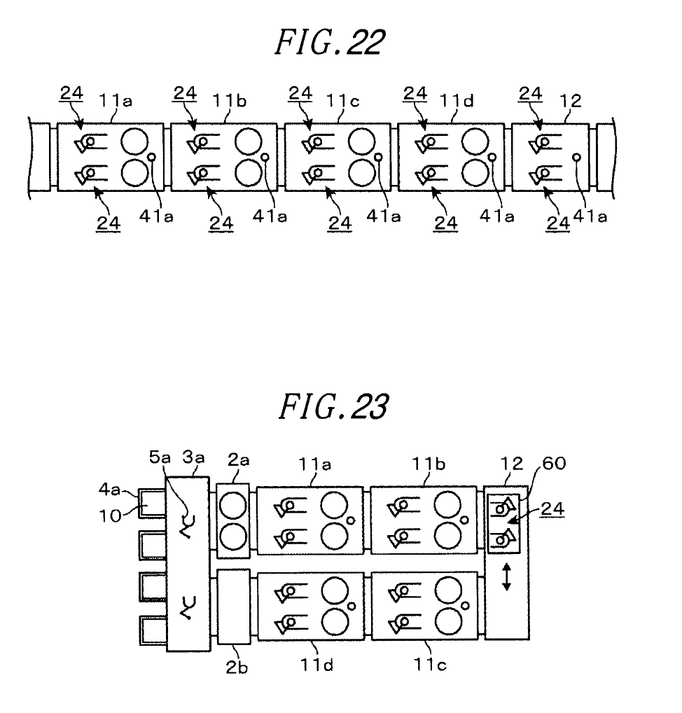

In this case, four processing units 11 (11a, 11b, 11c, 11d) are airtightly connected to each other, as shown in FIG. 22. In the processing unit 11b for performing a cleaning process, there is performed any one of a cleaning process for cleaning the surfaces of the wafers W by sputter etching of an Ar gas; a high temperature H₂ reduction process for reducing oxides of the surfaces of the wafers W by heating the wafers W to, e.g., about 400° C. or by supplying a H₂ gas while heating the wafers W; and a H₂ radical process for reducing oxides of the surfaces of the wafers W by supplying radicals of a H₂ gas to the surfaces of the wafers W by converting the H₂ gas into a plasma. Further, in the processing unit 11c for performing a film forming process of a Ta film, the targets 35 formed of Ta are arranged therein. Also in this case, the transfer operations of the wafers W are performed, e.g., at the same time in the processing units 11.

Further, in case of arranging four processing units 11, a removal process of moisture and the like, a film forming process of a titanium film by PVD, a film forming process of a ruthenium film by CVD, and a film forming process of a copper film by PVD may be sequentially performed.

Further, although the processing units 11 are arranged linearly in the above embodiments, for example, two rows of the processing units 11 may be arranged in parallel, as shown in FIG. 23. In this case, in order to transfer the wafers W between the processing unit 11 provided at one end portion of one row and the processing unit 11 at one end portion of the other row, the transfer module 12 may be configured to transfer the wafers W laterally between the one end portions of the two rows. In FIG. 23, four processing units 11 are arranged and a series of the processing units 11 is bent in two rows between the second and third processing units 11b and 11c from the upstream side. The transfer module 12 is airtightly connected to the sides of the processing units 11b and 11c, and the wafer transfer devices 24 are provided to be horizontally movable in parallel to the arrangement of the processing units 11b and 11c. In this case, the wafer transfer devices 24 are disposed on a common moving base 60, and the moving base 60 moves horizontally by a driving unit (not shown).

Further, in the third and forth processing units 11c and 11d from the upstream side, the mounting portions 23 and the wafer transfer devices 24 are arranged in reverse order as compared to those in the first and second processing units 11a and 11b from the upstream side. In other words, in the processing units 11c and 11d, the mounting portions 23 are disposed on the upstream side and the wafer transfer devices 24 are disposed on the downstream side. Accordingly, the wafer transfer devices 24 of the processing unit 11d serve as transport units for use in transferring the wafers W to the second load-lock chamber 2b in this embodiment.

By arranging the processing units 11 in a plurality of rows, one atmospheric transfer chamber may be used in common instead of the atmospheric transfer chambers 3a and 3b respectively connected to the first and the second load-lock chambers 2a and 2b. Accordingly, for example, it is possible to return the processed wafers W to the original FOUPs 10.

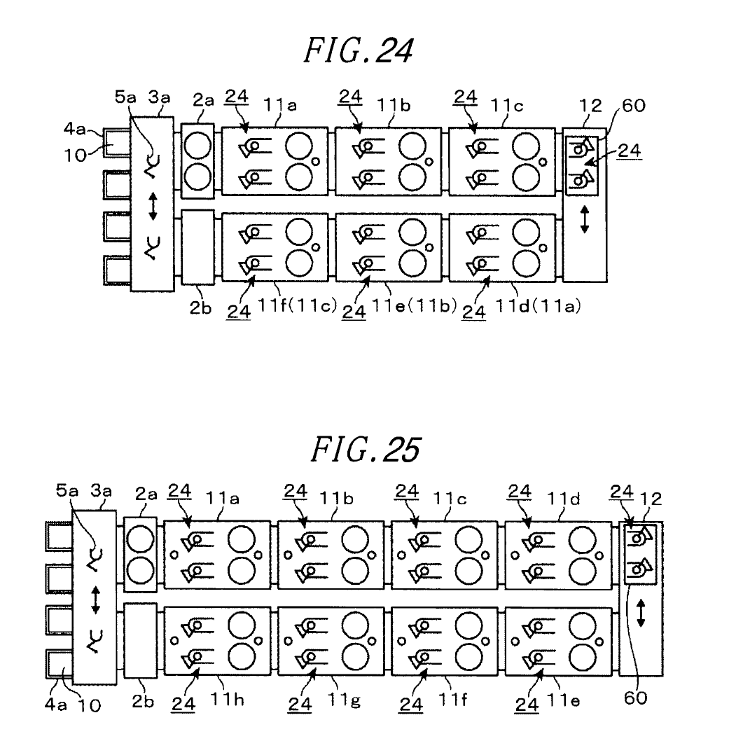

Further, as shown in FIG. 24, e.g., six processing units 11 (11a, 11b, 11c, 11d, 11e and 11f) may be connected to each other. In this embodiment, in the same way as in FIG. 23, a series of the processing units 11 is bent in two rows between the processing units 11c and 11d and the transfer module 12 is provided at the bent portion. In case of providing six processing units 11, different processes (serial process) may be respectively performed in the six processing units 11. Alternatively, three different processes may be performed in three processing units 11 located at the upstream side and three processing units 11 located at the downstream side, respectively, as described above. In this case, two serial processes are performed in parallel, and for example, the wafers W on which the serial process is performed in the processing units 11d, 11e and 11f at the downstream side pass through the processing units 11a, 11b and 11c at the upstream side in an unprocessed state (without being processed).

Further, as shown in FIG. 25, eight processing units (11a, 11b, 11c, 11d, 11e, 11f, 11g and 11h) may be connected to each other. In FIG. 25, a series of the processing units 11 is bent in two rows between the fourth and fifth processing units 11d and 11e from the upstream side, and the transfer module 12 is provided at the bent portion.

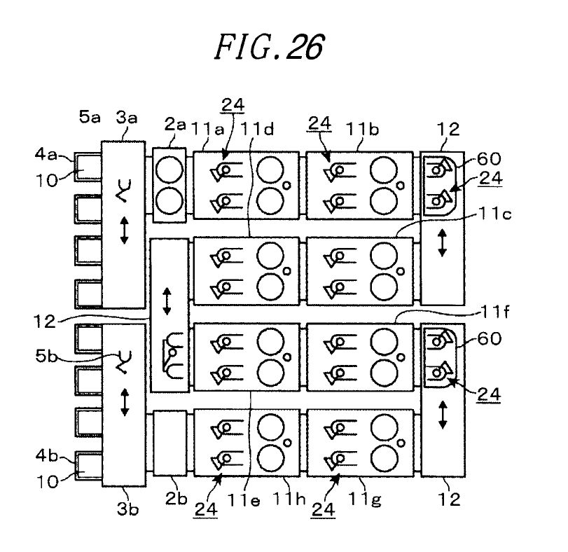

Further, as shown in FIG. 26, the eight processing units 11 (11a, 11b, 11c, 11d, 11e, 11f, 11g and 11h) may be bent in a plurality of (four in this embodiment) rows. In FIG. 26, two processing units 11 form one row, and four rows of the processing units 11 are arranged to have a zigzag shape. In other words, a series of the processing units 11 is bent between the second and third processing units 11b and 11c from the upstream side, between the fourth and fifth processing units 11d and 11e from the upstream side, and between the sixth and seventh processing units 11f and 11g. Further, the transfer modules 12 are airtightly connected to the bent portions, respectively.

Here, in transfer of the wafers W between the processing unit 11d and the processing unit 11e, the above-described support pins (not shown) for supporting the wafers W from the bottom side are disposed in the transfer module 12 connected to the processing units 11d and 11e at positions for performing the transfer of the wafers W between the wafer transfer devices 24 of the processing units 11d and 11e and the wafer transfer devices 24 of the transfer module 12, respectively. Specifically, when the wafer transfer devices 24 of the processing unit 11d load the wafers W on the support pins, the wafer transfer devices 24 of the transfer module 12 receive the wafers W, and load the corresponding wafers W on another support pins. Then, the wafer transfer devices 24 of the processing unit 11e receive the wafers W. By such procedure, the transfer of the wafers W is performed between the processing unit 11d and the processing unit 11e.

Although two atmospheric transfer chambers 3a and 3b are arranged in this embodiment, a common atmospheric transfer chamber may be used instead.

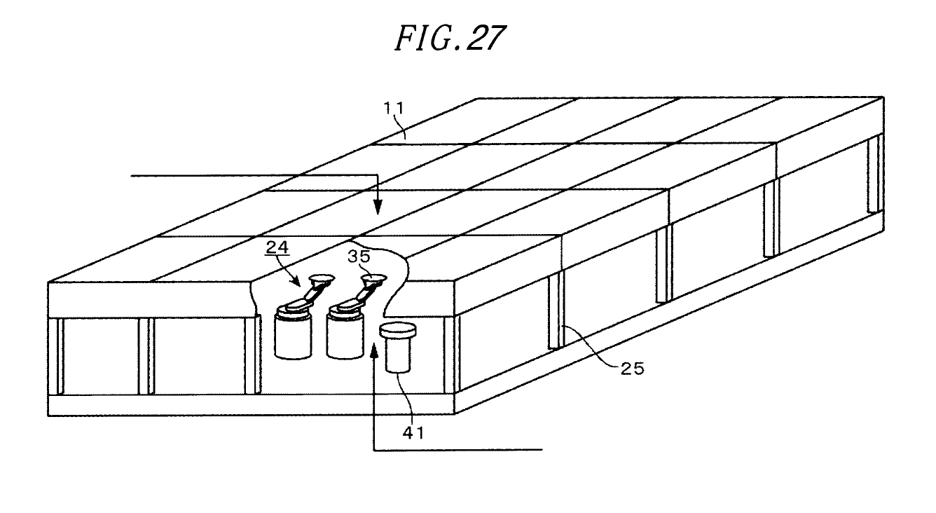

In a case where the process station 1 is bent in a plurality of rows, maintenance of the processing unit 11 with four sides surrounded by another processing units 11 and the first load-lock chamber 2a (or the second load-lock chamber 2b) or the transfer module 12 is performed as follows. With respect to, e.g., the targets 35 or the vacuum vessel 22, for instance, an operator moves on the upper sides of other processing units 11 and detaches, e.g., a ceiling portion (not shown) of the vacuum vessel 22 at the upper side of the corresponding processing unit 11 to perform maintenance. Further, with respect to the vacuum exhaust device 21, the driving units 42 of the wafer transfer devices 24 and the bottom side of the vacuum vessel 22, the operator moves through regions between the support members 25 provided on the lower surfaces of the vacuum vessels 22 and opens, e.g., the bottom surface of the vacuum vessel 22 at the lower side of the corresponding processing unit 11 to perform maintenance. Further, in FIG. 27, the first load-lock chambers 2a and the atmospheric transfer chambers 3a are omitted and the processing units 11 are partially cut off.

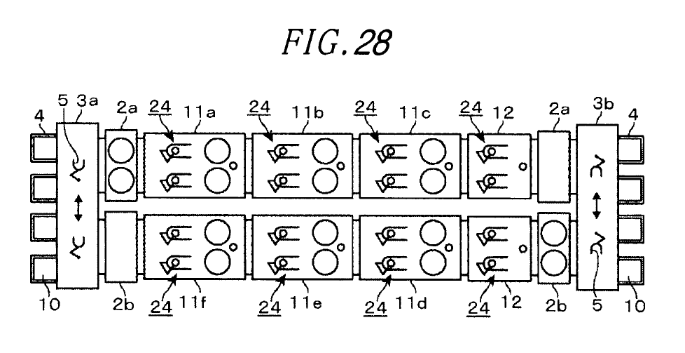

In the above embodiments in which a series of the processing units 11 is bent in a plurality of rows, the transfer module 12 for performing the transfer of the wafers W in a vacuum atmosphere is disposed at the bent portion. However, the transfer of the wafers W may be performed in the atmospheric atmosphere at the bent portion in another embodiment, which will be described with reference to FIG. 28.

In FIG. 28, six processing units 11 are provided and a series of the processing units 11 is bent in two rows. Further, the load-lock chambers 2 are arranged at one end portion and the other end portion of each row, respectively. The common atmospheric transfer chambers 3 are arranged between the load-lock chambers 2 at one end portions of the rows of the processing units 11 and between the load-lock chambers 2 at the other end portions of the rows of the processing units 11, respectively. Further, when the wafers W are transferred from one row of the processing units 11 to the other row of the processing units 11, the wafers W are transferred from the processing unit 11c to the processing unit 11d after sequentially passing through the transfer module 12, the load-lock chamber 2, the atmospheric transfer chamber 3, and the load-lock chamber 2 and transfer module 12. Further, as described above, in a case where the processing units 11 are arranged in two rows, different serial processes may be performed in the respective rows of the processing units 11.

Also in FIGS. 22 to 28, in the same way as in FIGS. 20 and 21, the same process (parallel process) or a serial process may be performed in the processing units 11.

As described above, in the embodiments of the present invention, the processing units 11 may be connected to each other in various manners depending on the types of the successive processes performed on the wafers W. Further, since an arrangement layout of the processing units 11 may be set freely, the vacuum processing apparatus of the present invention is an apparatus with a high degree of freedom.

Although the same process is performed on the mounting portions 23 in each of the processing units 11 in the above embodiments, different processes may be performed thereon. That is, for example, in a case where four processing units 11 are provided, while successive processes (a removal process of moisture and the like→a film forming process of a titanium (Ti) film→a film forming process of a titanium nitride (TiN) film→a film forming process of a tungsten (W) film) may be sequentially performed on one of two wafers W simultaneously transferred by the wafer transfer devices 24, successive processes (a removal process of moisture and the like→a film forming process of a tantalum (Ta) film→a film forming process of a ruthenium (Ru) film→a film forming process of a copper (Cu) film) may be sequentially performed on the other wafer. Appropriate compounds are selected for the targets 35 of the processing units 11, respectively, so as to form the above-mentioned films.

Further, as described above, in a case where different processes are performed on the mounting portions 23, films (film A→film A→film B→film B) may be stacked on one wafer W, while successive processes (a removal process of moisture and the like→an etching process→a film forming process of film C→a film forming process of film D) may be performed on the other wafer W. Further, the film A, film B, film C and film D are formed of different compounds, and each of the film A, film B, film C and film D is any one of the above-mentioned titanium (Ti) film, titanium nitride (TiN) film, tungsten (W) film, tantalum (Ta) film, ruthenium (Ru) film and copper (Cu) film.

Although two mounting portions 23 are provided in each of the processing units 11, only one mounting portion, or three or more mounting portions may be provided therein. In these cases, the wafer transfer devices 24 may be provided in accordance with the number of the mounting portions 23, Or one wafer transfer device 24 may have picks 24a respectively corresponding to the mounting portions 23. Further, the wafer transfer devices 24 for transferring the wafers W from the first load-lock chamber 2a to the processing unit 11 located at the upstream end of the process station 1, and the wafer transfer devices 24 for transferring the wafers W from the processing unit 11 located at the downstream end of the process station 1 to the second load-lock chamber 2b may be arranged in the first and the second load-lock chambers 2a and 2b, respectively. Further, the process station 1 may have a plurality of, e.g., two or more, processing units 11.

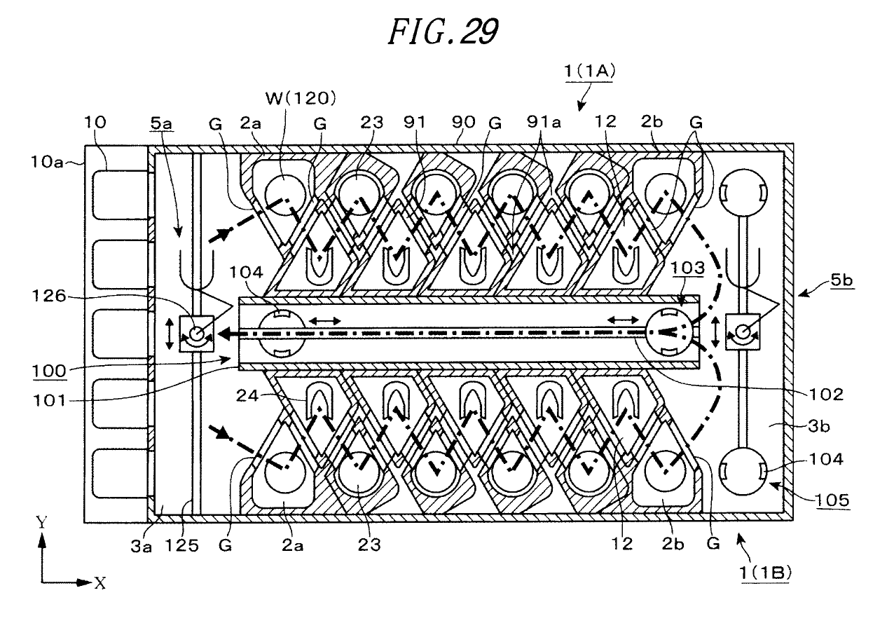

Next, a vacuum processing apparatus in accordance with another embodiment of the present invention will be described with reference to FIGS. 29 to 31. In the above-described embodiment of FIG. 1, the wafer transfer devices 24 and the processing units 11 are arranged to have a linear transfer path of the wafers W. However, in this embodiment, the process station 1 is configured to have a zigzag transfer path of the wafers W in order to reduce a foot print (length dimension of the process station 1 in the X direction) of the vacuum processing apparatus. Further, an atmospheric transfer path 100 is provided to quickly return the processed wafers W to the original FOUPs 10. By providing the atmospheric transfer path 100, the wafers W, which have reached the rear side in the apparatus when seen from a loading/unloading port 10a on which the FOUPs 10 are mounted, are transferred to the atmospheric transfer chamber 3a on the side of loading/unloading port 10a.

This embodiment will be described in detail. Using terms such as the front side and the rear side when viewed from the loading/unloading port 10a, in a rectangular housing 90 serving as an external main body of the apparatus, the first atmospheric transfer chamber 3a having an atmospheric atmosphere is provided at the front side and the second atmospheric transfer chamber 3b having an atmospheric atmosphere is provided at the rear side. The process stations 1 laterally separated from each other and extending from the front side to the rear side are arranged between the atmospheric transfer chambers 3a and 3b. The atmospheric transfer path 100 is provided linearly between the process stations 1 to return the processed wafers W in the process stations 1 from the second atmospheric transfer chamber 3b to the first atmospheric transfer chamber 3a. An inner atmosphere of the atmospheric transfer path 100 is an atmospheric atmosphere as will be described below.

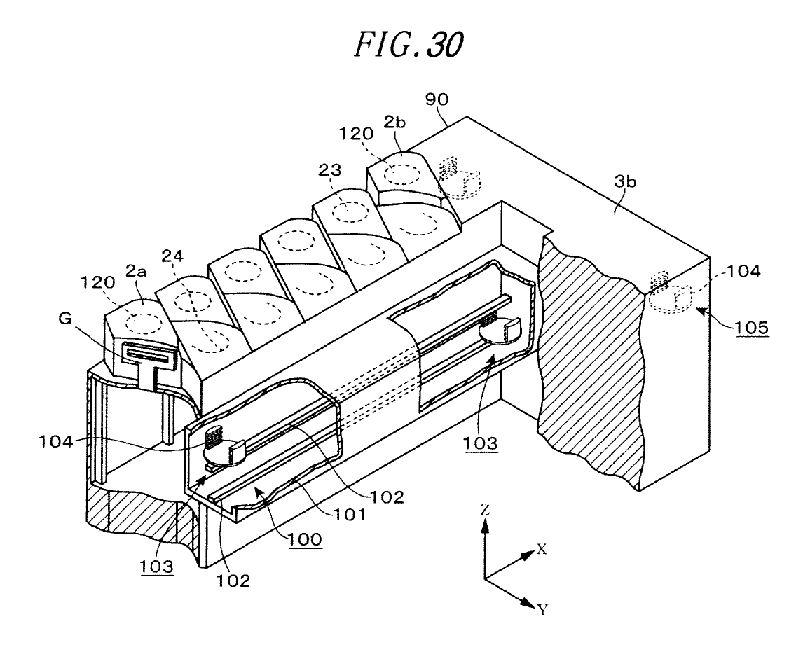

Further, in FIGS. 29 and 30, the same reference numerals are assigned to the same components as those in FIG. 1, and a description thereof is omitted. Further, the wafer transfer devices 24 and the transfer arms 5a and 5b are schematically illustrated.

Each of the process stations 1 is configured to have a zigzag transfer path of the wafers W as described above. Specifically, the first load-lock chamber 2a, a plurality of (four in this embodiment) processing units 11 and the second load-lock chamber 2b are sequentially arranged in a row from the first atmospheric transfer chamber 3a to the second atmospheric transfer chamber 3b along the atmospheric transfer path 100. Further, between the atmospheric transfer path 100 and the arrangement of the first and the second load-lock chambers 2a and 2b and the processing units 11, the wafer transfer devices 24 for transferring the wafers W from the upstream side to the downstream side in the arrangement as described above are disposed at five places in this embodiment. In FIG. 29, the transfer path of the wafers W in each of the process stations 1 is represented by a dashed dotted line.

Each of the wafer transfer devices 24 is positioned between the first load-lock chamber 2a (or the second load-lock chamber 2b) and the processing unit 11 (the mounting portion 23) adjacent to the first load-lock chamber 2a or between the adjacent processing units 11 when viewed from the atmospheric transfer path 100.

Specifically, when reference numeral 1A is assigned to the process station 1 on the left side in the two process stations 1, a partition wall 91 bent in a zigzag shape is arranged from the front side toward the rear side in the process station 1A. When reference numeral 91a is assigned to bent portions of the partition wall 91, installation regions of the wafer transfer devices 24 serving as transport units for use in transfer are formed between the bent portions 91a protruding toward the atmospheric transfer path 100 (to right side) to be positioned on the right of the partition wall 91. Further, the mounting portions 23 serving as processing regions are arranged between the bent portion 91a protruding to the left to be positioned on the left of the partition wall 91.

In this embodiment, although walls surrounding the installation regions of the wafer transfer devices 24 and walls of the mounting portions 23 are formed separately and partition valves (gate valves G) are provided between the walls, all of these walls are referred to as the partition wall 91 in this description.

Accordingly, when the processing regions (the mounting portions 23) are arranged in a forward and backward directions, each of the wafer transfer devices 24 is disposed on the right between the adjacent mounting portions 23 or between the first load-lock chamber 2a (or the second load-lock chamber 2b) and the mounting portion 23 adjacent to the first load-lock chamber 2a. Thus, an arrangement layout of the wafer transfer devices 24 and the mounting portions 23 has a zigzag shape. Therefore, when the arrangement of the first and the second load-lock chambers 2a and 2b and the mounting portions 23 is viewed from any one of the wafer transfer devices 24, the first load-lock chamber 2a or the processing unit 11 is disposed on the left front side through the gate valve G, and the processing unit 11 or the second load-lock chamber 2b is disposed on the right front side through the gate valve G.

When reference numeral 1B is assigned to the process station 1 on the right in the two process stations 1, the process station 1B is arranged to be symmetric to the process station 1A on the left with respect to the atmospheric transfer path 100. Specifically, in the process station 1B, five wafer transfer devices 24 are arranged on the side of the atmospheric transfer path 100, and the first and the second load-lock chambers 2a and 2b and four processing units 11 are linearly arranged on the right of the wafer transfer devices 24. Accordingly, each of the wafer transfer devices 24 in the process station 1B is disposed on the left between the adjacent mounting portions 23 or between the first load-lock chamber 2a (or the second load-lock chamber 2b) and the mounting portion 23 adjacent to the first load-lock chamber 2a.

The atmospheric transfer path 100 is provided in a transfer chamber 101 having an approximately box shape, which is arranged along the arrangement of the first and the second load-lock chambers 2a and 2b and the processing units 11 such that one end side and the other end side of the transfer chamber 101 communicate with the atmospheric transfer chambers 3a and 3b by being opened. Accordingly, an inner atmosphere of the transfer chamber 101 is set to an atmospheric (normal pressure) atmosphere. In the transfer chamber 101, there are provided rails 102 extending in a longitudinal direction of the transfer chamber 101, and wafer transfer sections 103 serving as transfer units movable in a horizontal direction (in a forward and a backward direction) along the rails 102. The wafer transfer section 103 includes, as shown in FIG. 30, supporting portions 104 for supporting the peripheries of the wafers W, which are vertically provided at a plurality of places such that a plurality of wafers W can be loaded at different heights.

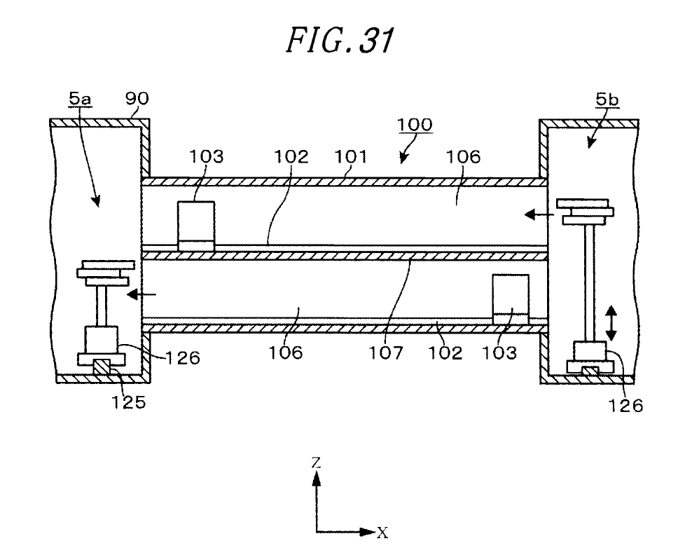

In the transfer chamber 101, two transfer paths 106 of the wafers W are stacked vertically. Specifically, one rail 102 and one wafer transfer section 103 form one set and two sets thereof are provided to be separated from each other in a vertical direction. The transfer paths 106 are divided vertically by a partition plate 107 as shown in FIG. 31. The transfer arm 5a (or 5b) is configured to be vertically movable by an elevation mechanism 126 provided at the bottom side of the atmospheric transfer chamber 3a (or 3b) to perform the transfer of the wafers W from and to the wafer transfer sections 103. In the atmospheric transfer chamber 3b, wafer receiving parts 105 are provided at two places to be separated from each other in a lateral direction to cool the processed wafers W, and the supporting portions 104 are provided vertically at a plurality of places in each of the wafer receiving parts 105.

In FIG. 31, reference numeral 125 denotes a rail along which the transfer arm 5a (or 5b) is movable in a horizontal direction (in a lateral direction). Further, in FIG. 30, the atmospheric transfer chamber 3a and a part of the process stations 1 are cut off and the transfer arm 5b is omitted. Further, the partition plate 107 is omitted in FIG. 30, and a part of the atmospheric transfer chambers 3a and 3b is omitted in FIG. 31.

In this vacuum processing apparatus, while the wafers W are sequentially processed in the processing units 11, the wafers W are transferred together (simultaneously) from the upstream side to the downstream side. Further, the wafers W unloaded from the second load-lock chamber 2b at the downstream side are received in the wafer transfer section 103 after being cooled by being temporarily mounted on the wafer receiving parts 105, or without passing through the wafer receiving parts 105 (without being cooled). Then, the wafer transfer section 103 moves toward the atmospheric transfer chamber 3a at the upstream side immediately when one processed wafer W is received thereon or after a plurality of wafers W are received thereon. Subsequently, while another (empty) wafer transfer section 103 moves toward the downstream side, the transfer arm 5a unloads the wafers W from the wafer transfer section 103 and loads the wafers W to, e.g., the original FOUPs 10.

In this embodiment, the first and the second load-lock chambers 2a and 2b and the processing units 11 are arranged in a row and the wafer transfer devices 24 are arranged to face regions between the first load-lock chamber 2a (or the second load-lock chamber 2b) and the processing unit 11 adjacent to the first load-lock chamber 2a and between the adjacent processing units 11 from the lateral side (the side of the atmospheric transfer path 100) such that a transfer path of the wafers W has a zigzag shape. Accordingly, it is possible to reduce a foot print (length dimension in the X direction) of the vacuum processing apparatus.

Further, since the wafer transfer sections 103 are provided, the processed wafers W can be simultaneously transferred to the FOUPs 10, thereby performing processing on the wafers W with a high throughput. Further, when the wafers W are transferred from the upstream side to the downstream side by the wafer transfer devices 24, there is no need for the wafer transfer devices 24 to be rotated by 180 degrees. In other words, when the arrangement of the processing units 11 is viewed from the wafer transfer devices 24, both the loading opening 43a of the upstream side and the unloading opening 43b of the downstream side are arranged at the front side to be separated from each other laterally. Therefore, a rotation operation of the wafer transfer device 24 can be completed for a very short period of time, thereby improving a throughput.

Although the common atmospheric transfer path 100 is provided for the two process stations 1 in this embodiment, the atmospheric transfer path 100 may be individually provided for each of the process stations 1. Further, one process station 1 and one atmospheric transfer path 100 may be provided only. Further, the regions corresponding to the atmospheric transfer chambers 3a and 3b and the atmospheric transfer path 100 may have a normal pressure atmosphere containing, e.g., a nonreactive gas such as a nitrogen gas, without being limited to the atmospheric atmosphere.

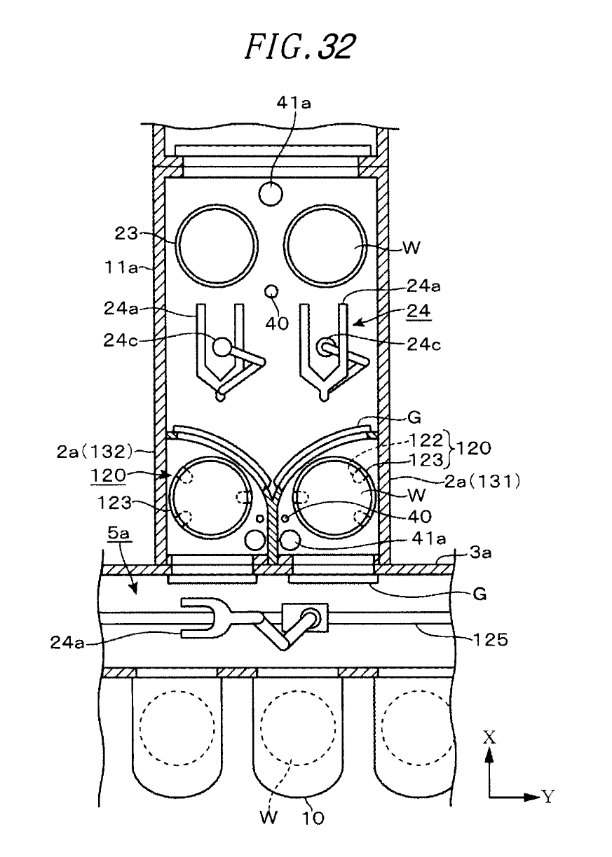

Next, the preferable configurations of the first and the second load-lock chambers 2a and 2b applicable to the vacuum processing apparatus will be described by using an example of the vacuum processing apparatus shown in FIG. 1 with reference to FIGS. 32 to 45. The first load-lock chamber 2a is configured such that when the wafers W are transferred to the processing unit 11a located at the upstream end, atmosphere conversion time required for conversion of the atmosphere of the first load-lock chamber 2a (vacuum evacuation or air introduction) does not become the rate limiting factor of the total processing time of the vacuum processing apparatus, or the atmosphere conversion time does not become the rate limiting factor of the processing time as far as possible. Further, the second load-lock chamber 2b is configured such that when the wafers W are unloaded from the transfer module 12 located at the downstream end of the process station 1, similarly, the atmosphere conversion time does not become the rate limiting factor of the total processing time of the vacuum processing apparatus, or the atmosphere conversion time does not becomes the rate limiting factor of the processing time as far as possible.

Specifically, the first load-lock chambers 2a (or the second load-lock chambers 2b) are provided at two places to be separated from each other laterally. While loading and unloading of the wafers W are performed in one of the first load-lock chambers 2a (or the second load-lock chambers 2b), the transfer of the next wafers W is prepared in the other one of the first load-lock chambers 2a (or the second load-lock chambers 2b). Since the first and the second load-lock chambers 2a and 2b have the same configuration, the first load-lock chambers 2a located at the upstream side will be described. Further, FIG. 32 illustrates an enlarged view of a region in the vicinity of the first load-lock chambers 2a in the vacuum processing apparatus.

The first load-lock chambers 2a are provided at two places to be separated from each other laterally as described above. Each of the first load-lock chambers 2a has a loading portion 120 for vertically loading a plurality of, e.g., four wafers W at different heights. The loading portion 120 is formed in an approximately circular shape in the plan view and vertically movable by an elevation member 121 provided at the bottom side of the first load-lock chamber 2a.

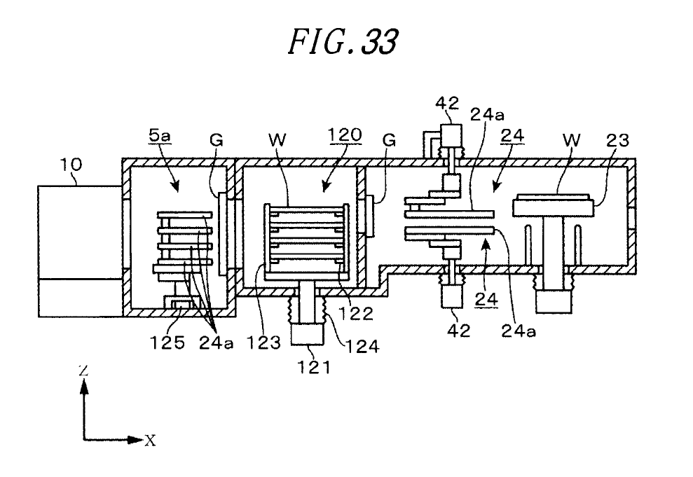

In FIG. 32, reference numeral 122 denotes support portions for supporting the peripheries of the wafers W from the bottom side, and reference numeral 123 denotes support columns for vertically arranging the support portions 122. Further, in FIG. 33, reference numeral 124 denotes a bellows. Further, in FIG. 32, reference numeral 40 denotes an opening of a gas supply line, and reference numeral 41a denotes a gas exhaust opening.

In the transfer arm 5a (or 5b), four picks 24a for supporting the wafers W from the bottom side are arranged vertically to correspond to loading pitches of the wafers W in the loading portion 120. Accordingly, the transfer arm 5a is configured to simultaneously unload the four wafers W from the FOUPs 10, and simultaneously load the wafers W into the first load-lock chamber 2a. In FIG. 33, reference numeral 125 denotes a rail along which the transfer arm 5a is movable in a lateral direction. Further, the dimension of the FOUPs 10 or the dimension of the transfer arm 5a and the loading portion 120 are schematically illustrated.

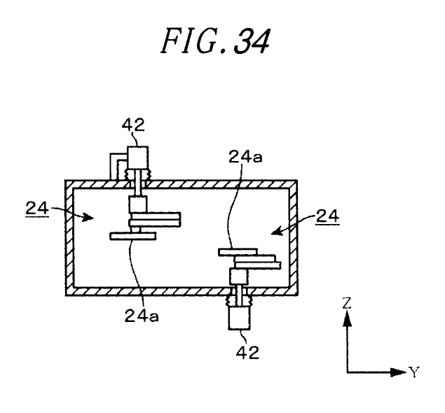

The vacuum processing apparatus of this embodiment is configured such that the two wafer transfer devices 24 respectively located at the downstream sides of the first load-lock chambers 2a can simultaneously access one of the first load-lock chambers 2a or the other one of the first load-lock chambers 2a. Specifically, as shown in FIGS. 33 and 34, the driving unit 42 of one of the two wafer transfer devices 24 separated from each other laterally (the left one when viewed from the atmospheric transfer chamber 3a) is provided above the ceiling surface of the vacuum vessel 22. Further, a vertical position of the pick 24a in one of the wafer transfer devices 24 is set such that a support (transfer) position of the wafer W is higher than a support (transfer) position of the wafer W in the other one of the wafer transfer devices 24. That is, the picks 24a of the wafer transfer devices 24 are set to be separated from each other to correspond to the pitches of the support portions 122 of the loading portion 120 such that, e.g., one wafer W and an upper or lower wafer W adjacent to the corresponding wafer W can be simultaneously unloaded from the loading portion 120. Further, FIG. 34 illustrates a longitudinal cross sectional view of the wafer transfer devices 24 in a state viewed from the atmospheric transfer chamber 3a.

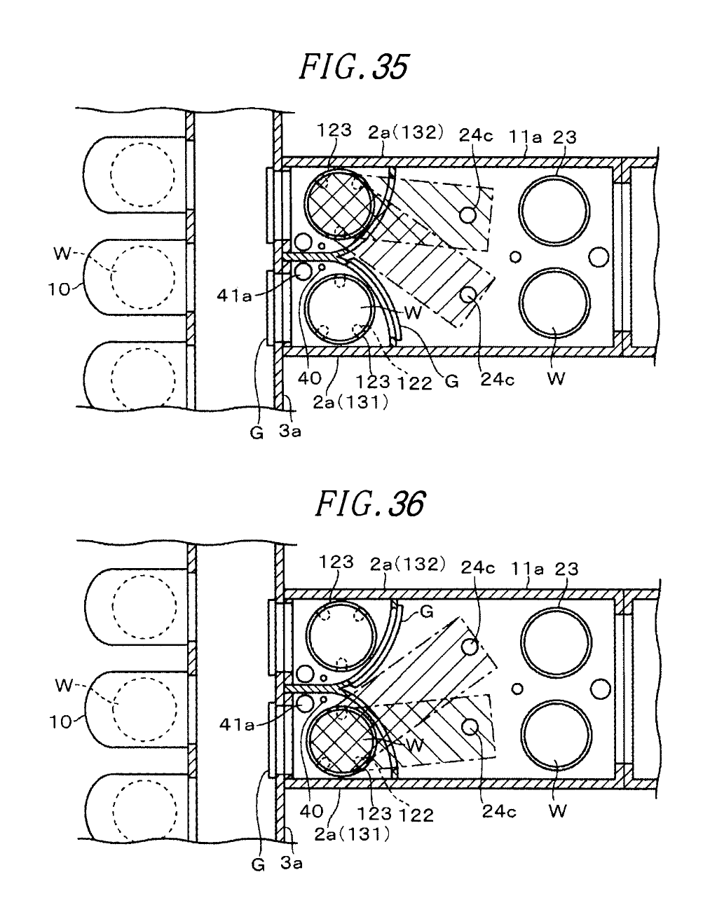

Further, the gate valves G of the first load-lock chambers 2a on the side of the wafer transfer devices 24 are formed in an approximately circular arc shape to protrude outward (toward the wafer transfer devices 24) along an external shape of the loading portion 120 in order not to interfere (collide) with the transfer operations of the wafer transfer devices 24 and the wafers W transferred by the wafer transfer devices 24. Accordingly, as shown in FIGS. 35 and 36, when the wafer transfer devices 24 simultaneously access one of the two first load-lock chambers 2a, the wafers W transferred by the wafer transfer devices 24 do not collide with the gate valve G of the other one of the first load-lock chambers 2a even though the gate valve G of the other one of the first load-lock chambers 2a on the side of the wafer transfer devices 24 is closed. Further, in FIGS. 35 and 36, the outlines of the wafers W transferred by the wafer transfer devices 24 are represented by dashed dotted lines, and the wafer transfer devices 24 are omitted.

The second load-lock chamber 2b, the wafer transfer devices 24 in the transfer module 12 and the transfer arm 5b in the atmospheric transfer chamber 3b, which are located at the downstream side, are configured in the same way as the first load-lock chambers 2a, the wafer transfer devices 24 and transfer arm 5a, which are located at the upstream side and described above.

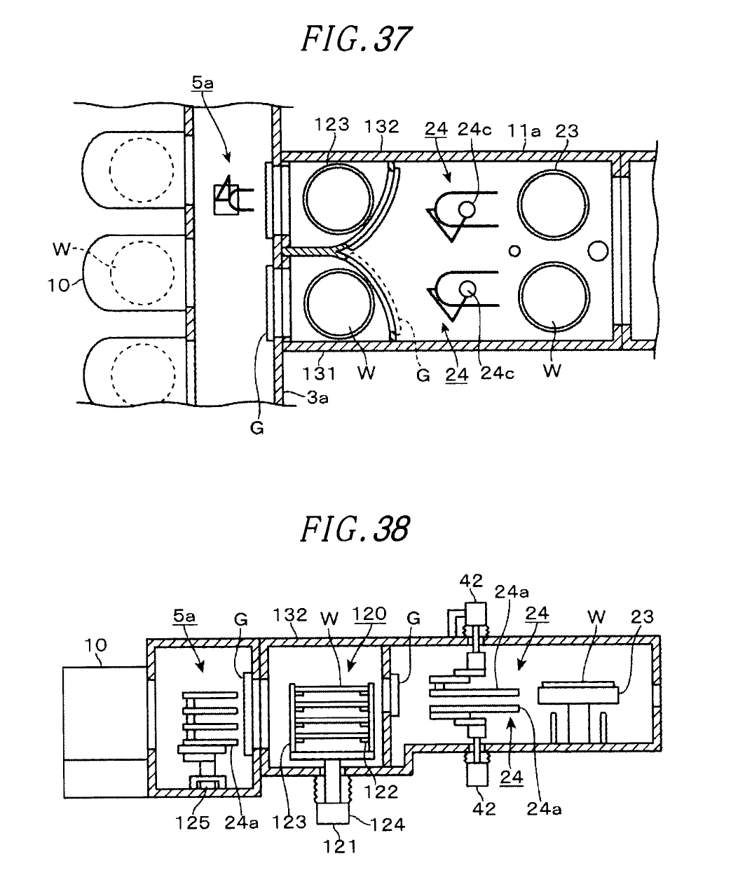

Next, the effects of the vacuum processing apparatus will be described with reference to FIGS. 37 to 45. First of all, while the processes and transfers of the wafers W are continuously performed in the vacuum processing apparatus, one of the two first load-lock chambers 2a (the right one when viewed from the atmospheric transfer chamber 3a) (hereinafter, designated by reference numeral 131) is empty (in a state where the last wafer W has been unloaded) as shown in FIGS. 37 and 38. Further, in the other one of the first load-lock chambers 2a (hereinafter, designated by reference numeral 132), four wafers W are received and the first and second wafers W from the top side are set at positions facing the loading opening 43a. In this case, the gate valve G of the load-lock chamber 131 on the side of the wafer transfer devices 24 is opened, and the gate valve G of the load-lock chamber 132 is closed because the load-lock chamber 132 is vacuum evacuated. At this time, the mounting portions 23 have the wafers W thereon and the above-described processes are performed on the wafers W.

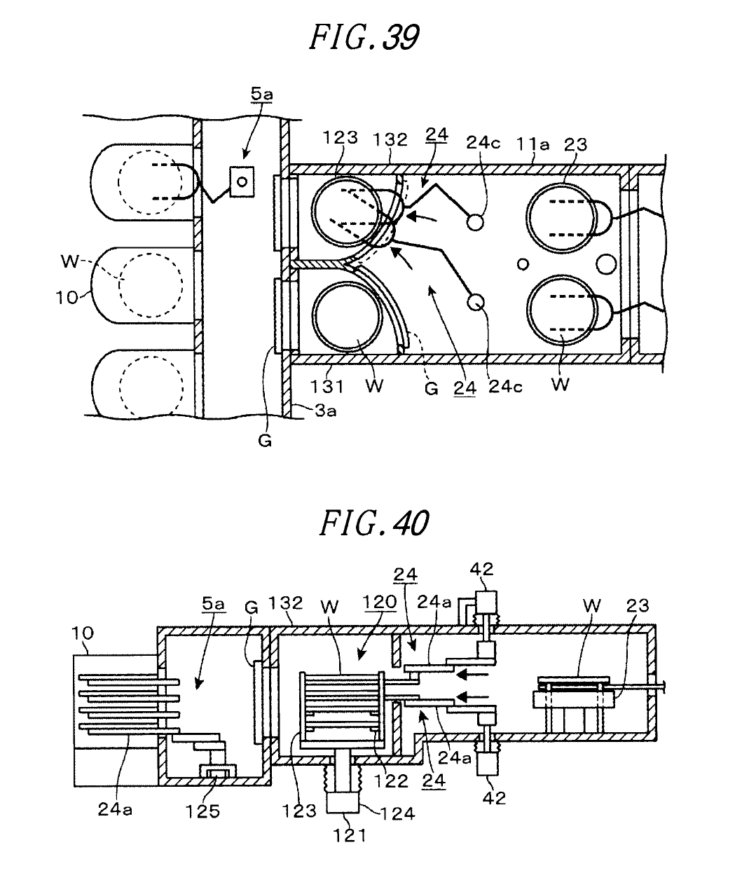

First, when the vacuum evacuation of the load-lock chamber 132 is completed, the gate valve G of the load-lock chamber 132 on the side of the wafer transfer devices 24 is opened. Further, when the wafers W are completely processed on the mounting portions 23, the wafer transfer devices 24 simultaneously access the load-lock chamber 132 to unload, e.g., the first and second wafers W from the top side from the load-lock chamber 132 as shown in FIGS. 39 and 40. Specifically, the wafer transfer devices 24 are driven such that the picks 24a of the wafer transfer devices 24 are positioned below the wafers W, and then the wafers W are received on the wafer transfer devices 24 by slightly moving the loading portion 120 down. Thereafter, the picks 24a are retreated toward the wafer transfer devices 24.

In this case, the wafer transfer devices 24 located at the downstream side of the processing unit 11a access the processing unit 11a to transfer the processed wafers W into the processing unit 11b located at the downstream side of the processing unit 11a. The transfer operations of the wafer transfer devices 24 of the processing unit 11a and the transfer operations of the wafer transfer devices 24 of the processing unit 11b are simultaneously performed as described above. Further, the gate valve G of the load-lock chamber 131 on the side of the wafer transfer devices 24 is closed, and the inner atmosphere of the load-lock chamber 131 is changed to the atmospheric atmosphere. Further, the transfer arm 5a moves toward the FOUP 10 and simultaneously unloads, e.g., four unprocessed wafers W from the FOUP 10.

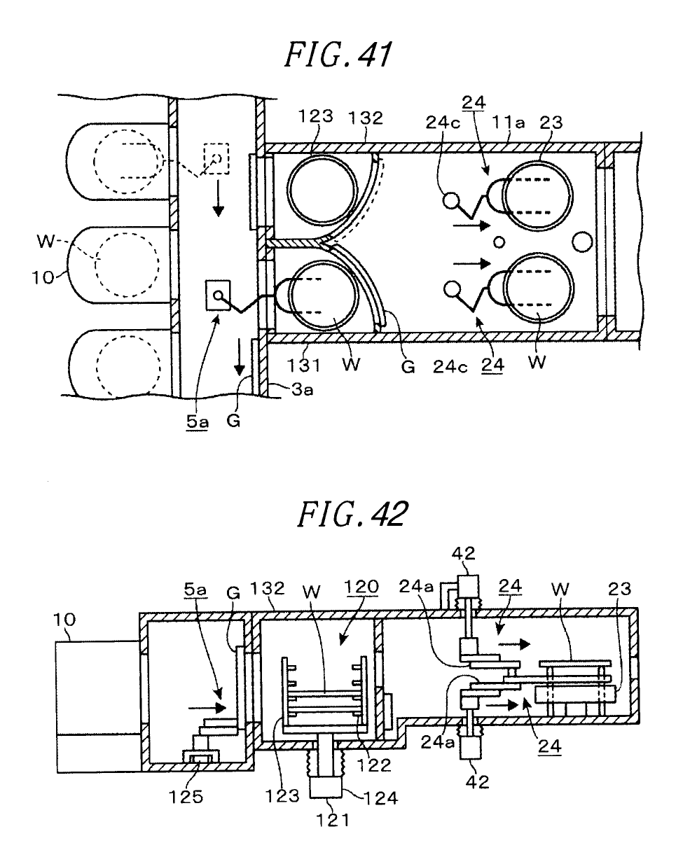

Subsequently, the wafer transfer devices 24 on which the wafers W are being received from the load-lock chamber 132, simultaneously load the wafers W on the mounting portions 23 as shown in FIGS. 41 and 42. Further, the gate valve G on the side of the atmospheric transfer chamber 3a is opened in the load-lock chamber 131 having an atmospheric atmosphere therein and, e.g., four wafers W are simultaneously loaded into the load-lock chamber 131 by the transfer arm 5a.

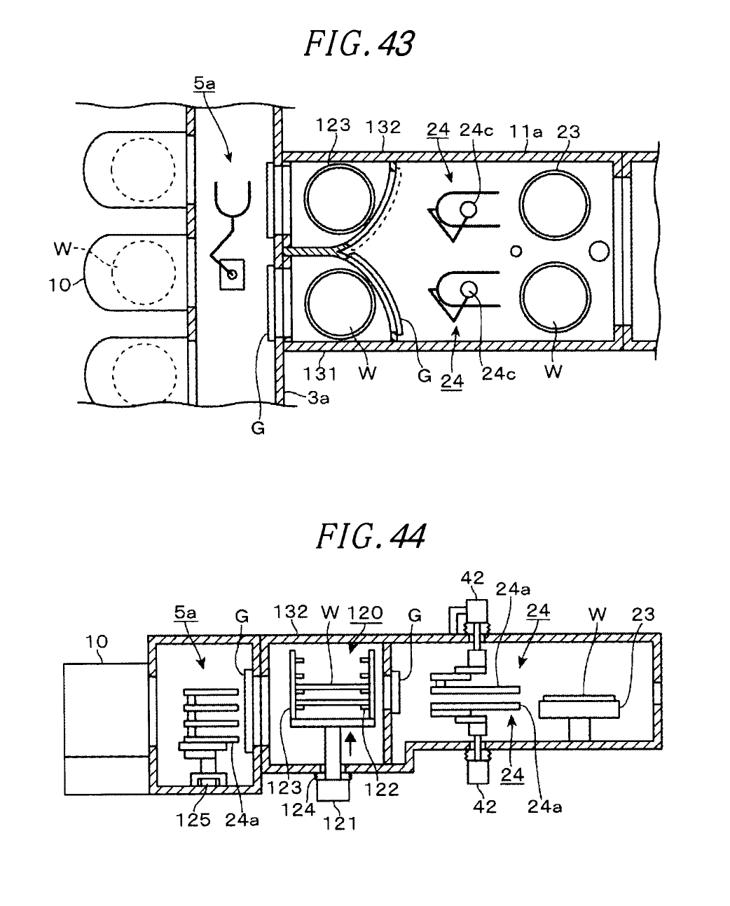

The wafer transfer devices 24 are retracted to the original positions and stand by until the processes are completed on the mounting portions 23 as shown in FIGS. 43 and 44. In the load-lock chamber 131, the gate valve G on the side of the atmospheric transfer chamber 3a is airtightly closed to start vacuum evacuation. In the load-lock chamber 132, the loading portion 120 is moved up such that the wafers W are positioned to face the loading opening 43a in order that the third and fourth wafers W from the top side are transferred to the wafer transfer devices 24. Further, when the processes are completed on the mounting portions 23, the wafers W are transferred to the downstream side as shown in FIGS. 39 to 42. Then, in the empty load-lock chamber 132, the gate valve G on the side of the wafer transfer devices 24 is closed, and air is introduced in order to load the unprocessed wafers W. At the same time, in the load-lock chamber 131, the gate valve G on the side of the wafer transfer devices 24 is opened when vacuum evacuation is completed.

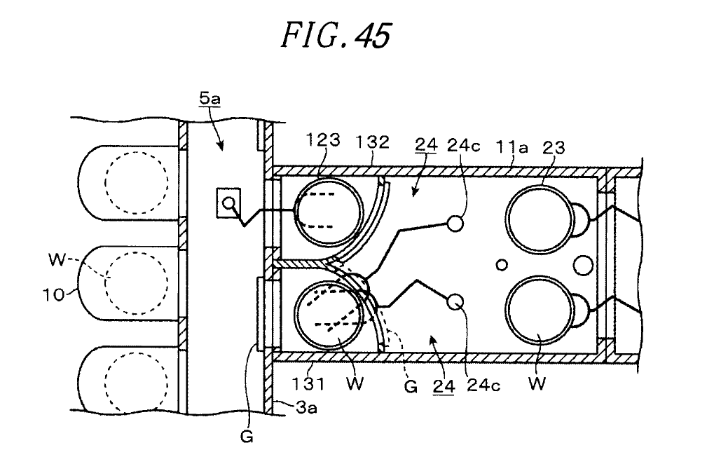

As described above, as shown in FIG. 45, loading of the wafers W by the transfer arm 5a and unloading of the wafers W by the wafer transfer devices 24 are alternately performed with respect to the load-lock chambers 131 and 132. Further, loading and unloading of the wafers W are alternately performed in the same way with respect to the second load-lock chambers 2b located at the downstream side. Accordingly, since the wafer transfer devices 24 alternately uses the two first load-lock chambers 2a (or the two second load-lock chambers 2b), it is unnecessary to wait unloading of the wafers W until vacuum evacuation or air introduction is completed in the first load-lock chambers 2a (or the second load-lock chambers 2b).

Accordingly, the atmosphere conversion time required for conversion of the atmosphere of the first load-lock chamber 2a (or the second load-lock chamber 2b) does not become the rate limiting factor of the total processing time of the vacuum processing apparatus, or the atmosphere conversion time hardly becomes the rate limiting factor of the total processing time. Therefore, the loading of the wafers W into the upstream end of the process station 1 and the unloading of the wafers W from the downstream end of the process station 1 can be continuously, normally and further quickly performed even when the processes are performed at a high speed in the processing units 11, so that the processes are performed with a high throughput.

In this case, a plurality of (specifically, an even number of four or more) wafers W are accommodated in the first load-lock chambers 2a (or the second load-lock chambers 2b), so that it is possible to lengthen the time taken for the wafer transfer devices 24 to access the first load-lock chambers 2a (or the second load-lock chambers 2b). Accordingly, vacuum evacuation or air introduction of the first load-lock chambers 2a (or the second load-lock chambers 2b) may be performed for the time taken for the wafer transfer devices 24 to access the first load-lock chambers 2a (or the second load-lock chambers 2b). That is, as described above, the vacuum evacuation or air introduction of the first load-lock chambers 2a (or the second load-lock chambers 2b) may be performed such that it does not become rate limiting factor of processing in the processing units 11. In other words, a plurality of wafers W are received in the first load-lock chambers 2a (or the second load-lock chambers 2b), so that it is possible to quickly perform vacuum evacuation of the first load-lock chambers 2a (or the second load-lock chambers 2b) without the large-sized vacuum exhaust device 21. Accordingly, processing can be performed with a high throughput and it is possible to suppress an increase in cost of the apparatus. Further, since the wafer transfer devices 24 simultaneously access the first load-lock chambers 2a (or the second load-lock chambers 2b), it is possible to largely enhance the throughput as compared with a case in which the wafer transfer devices 24 alternately perform loading (unloading) of the wafers W.

The following table shows the operation sequence of the wafer transfer devices 24 and the like in FIGS. 39 to 45 and the time actually required for the operation sequence. “VA1” and “VA2” represent one and the other one of the two wafer transfer devices 24, respectively. “LL1” and “LL2” represent the load-lock chambers 131 and 132, respectively. Further, “STG1” and “STG2” represent one and the other one of the two mounting portions 23 provided at the downstream side of the wafer transfer devices 24, respectively. “Slot” means a mounting position of the wafer W in the loading portion 120, and subscripts “1 to 4” following “slot” represent a loading position of the wafer W from the top side. Further, “VA access” represents a state where the wafer transfer devices 24 are accessing the load-lock chamber 131 (or 132). “VENT” and “VAC” represent air introduction and vacuum evacuation, respectively. “AA access” represents loading of the wafers W by the transfer arm 5a. Further, “get” represents an operation in which the wafer transfer devices 24 unload the wafers W from the load-lock chamber 131 (or 132), and “put” represents an operation in which the wafers W are mounted on the mounting portions 23.

TABLE

| | | | | Time |
|---|---|---|---|---|
| | | | | required |
| LL1 | LL2 | VA1 | VA2 | (seconds) |
| VA access | VENT | getLL1slot1 | getLL1slot2 | 5 |
| | AA access | putSTG1 | putSTG2 | 5 |
| | VAC | getLL1slot3 | getLL1slot4 | 5 |
| VENT | | putSTG1 | putSTG2 | 5 |
| | VA access | getLL2slot1 | getLL2slot2 | 5 |
| AA access | | putSTG1 | putSTG2 | 5 |
| VAC | | getLL2slot3 | getLL2slot4 | 5 |
| | VENT | putSTG1 | putSTG2 | 5 |

As represented in the above table, when each operation of the wafer transfer devices 24 is performed for five seconds, the load-lock chamber 131 (or 132) is allowed to perform vacuum evacuation or air introduction therein for the longer time, e.g., for ten seconds in this example. Accordingly, it is possible to transfer (process) seven hundred twenty wafers W per one hour.

Although the first load-lock chambers 2a (or the second load-lock chambers 2b) are arranged in a lateral direction in this embodiment, they may be arranged in a vertical direction. In this case, the wafer transfer devices 24 and the transfer arm 5a are configured to be vertically movable to access the first load-lock chambers 2a (or the second load-lock chambers 2b).

Although four wafers W are received in each of the first load-lock chambers 2a (or the second load-lock chambers 2b) in the above embodiment, a plurality of, e.g., six or more wafers W may be received in each of the first load-lock chambers 2a (or the second load-lock chambers 2b). In this case, the first load-lock chambers 2a (or the second load-lock chambers 2b) are also allowed to perform vacuum evacuation or air introduction therein for a longer time. Further, although the loading portion 120 in the first load-lock chambers 2a (or the second load-lock chambers 2b) is vertically moved, the wafer transfer devices 24 may be vertically movable. In other words, the pick 24a provided at the upper wafer transfer device 24 may be configured to access the first and third wafers W of the loading portion 120, while the pick 24a provided at the lower wafer transfer device 24 may be configured to access the second and fourth wafers W. Further, although the vertical positions of the picks 24a of the upper and the lower wafer transfer device 24 are set to unload the first and second wafers W and then unload the third and fourth wafers W from the loading portion 120, after the first and third wafers W are unloaded, the second and fourth wafers W may be unloaded.

In the above embodiments, when the wafer transfer devices 24 simultaneously access the load-lock chamber 131 (or 132), “simultaneously” not only represents the same timing, but also includes, e.g., a case where the time periods of the transfer operations of the wafer transfer devices 24 partially overlap with each other.

According to the above embodiments, a plurality of processing regions for performing vacuum processing are arranged in a row at intervals, and the transport units are provided between the processing regions. Accordingly, in the entire transfer operations in which the substrates are respectively transferred to the subsequent downstream processing regions from the first preliminary vacuum chamber to the processing region located at the downstream end of the series of the processing regions, time periods of at least two transfer operations partially or totally overlap with each other. Therefore, it is possible to reduce an entire foot print of the apparatus and it is also possible to shorten the time from the vacuum processing completion on the wafers to the starting of subsequent vacuum processing on the next wafers performed in the respective processing regions.

While the invention has been shown and described with respect to the embodiments, it will be understood by those skilled in the art that various changes and modification may be made without departing from the scope of the invention as defined in the following claims.

What is claimed is:

1. A vacuum processing apparatus for performing vacuum processing on substrates, comprising:
a first preliminary vacuum chamber to which the substrates are loaded from a normal pressure atmosphere;
a process station connected to the first preliminary vacuum chamber and maintained in a vacuum atmosphere;
a second preliminary vacuum chamber connected to the process station, the substrates processed in the process station being unloaded from the process station to a normal pressure atmosphere; and
a control unit for controlling an operation of the vacuum processing apparatus,
wherein the process station includes:
a series of processing regions arranged in a row at intervals to perform vacuum processing on the substrates, the substrates being sequentially transferred from the processing region located at an upstream side to the processing region located at a downstream side;
a first transport unit for transferring the substrates in the first preliminary vacuum chamber to the processing region located at an upstream end of the series of the processing regions;
a second transport unit arranged between the processing regions adjacent to each other; and
a third transport unit for transferring the substrates from the processing region located at a downstream end of the series of the processing regions to the second preliminary vacuum chamber, and
wherein the control unit outputs a control signal such that in the transfer operations in which the substrates are respectively transferred to the subsequent downstream processing regions therefor from the first preliminary vacuum chamber to the processing region located at the downstream end of the series of the processing regions, time periods of at least two transfer operations partially or totally overlap with each other.

2. The vacuum processing apparatus of claim 1, wherein the control unit outputs a control signal such that all of the transfer operations are performed simultaneously.

3. The vacuum processing apparatus of claim 1, wherein the processing regions, the first transport unit, the second transport unit and the third transport unit are arranged in a common vacuum vessel.

4. The vacuum processing apparatus of claim 1, wherein each of the processing regions is separated from at least one of an installation region of the transport unit adjacent to the upstream side thereof and an installation region of the transport unit adjacent to the downstream side thereof by a partition wall and a partition valve is provided at the partition wall to airtightly separate the regions from each other, and
wherein the transport unit transfers the substrates through the partition valve.

5. The vacuum processing apparatus of claim 1, wherein the processing regions are linearly arranged, the first preliminary vacuum chamber is disposed at one end of the series of the processing regions, and the second preliminary vacuum chamber is disposed at the other end of the series of the processing regions.

6. The vacuum processing apparatus of claim 1, wherein the series of the processing regions includes a plurality of rows of the processing regions arranged in parallel,
wherein in adjacent rows of the processing regions, a transport unit is provided to transfer the substrates between the processing region located at one end of one of the adjacent rows of the processing regions and the processing region located at one end of the other one of the adjacent rows of the processing regions, and
wherein the series of the processing regions arranged in parallel forms one substrate transport path having a bent shape.

7. The vacuum processing apparatus of claim 1, wherein when an arrangement direction of the processing regions is a forward and backward direction, the second transport unit is disposed on a left or right side between the processing regions adjacent to each other, so that an arrangement layout of the second transport unit and the processing regions is formed in a zigzag shape.

8. The vacuum processing apparatus of claim 1, further comprising:
a first normal pressure transfer chamber and a second normal pressure transfer chamber respectively disposed to correspond to the first preliminary vacuum chamber and the second preliminary vacuum chamber;
a first transfer unit disposed in the first normal pressure transfer chamber to transfer the substrates to the first preliminary vacuum chamber and a second transfer unit disposed in the second normal pressure transfer chamber to receive the substrates from the second preliminary vacuum chamber; and
a normal pressure transfer path having a normal pressure atmosphere arranged along the series of the processing regions to transfer the processed substrates from the second normal pressure transfer chamber to the first normal pressure transfer chamber, wherein a transfer device is disposed in the normal pressure transfer path to transfer the processed substrates.
